(19) United States
(12) Patent Application Publication
(10) Pub. No.: US 2024/0379328 A1
(43) Pub. Date: Nov. 14, 2024

(54) PULSED VOLTAGE SOURCE FOR PLASMA PROCESSING APPLICATIONS

(71) Applicant: Eagle Harbor Technologies, Inc., Seattle, WA (US)

(72) Inventors: Timothy M. Ziemba, Bainbridge Island, WA (US); Kenneth E. Miller, Seattle, WA (US); James R. Prager, Seattle, WA (US); John G. Carscadden, Seattle, WA (US)

(21) Appl. No.: 18/776,242

(22) Filed: Jul. 17, 2024

Related U.S. Application Data
(63) Continuation-in-part of application No. 18/493,515, filed on Oct. 24, 2023.
Application No. 18/493,515 is a continuation of application No. 17/411,028, filed on Aug. 24, 2021, now Pat. No. 11,810,761.
Application No. 17/411,028 is a continuation-in-part of application No. 17/231,923, filed on Apr. 15, 2021, now Pat. No. 11,587,768.
Application No. 17/231,923 is a continuation-in-part of application No. 16/537,513, filed on Aug. 9, 2019, now Pat. No. 11,227,745.
Application No. 16/537,513 is a continuation-in-part of application No. 16/721,396, filed on Dec. 19, 2019, now Pat. No. 11,075,058.
Application No. 16/721,396 is a continuation-in-part of application No. 16/722,115, filed on Dec. 20, 2019, now Pat. No. 11,222,767.
Application No. 16/722,115 is a continuation-in-part of application No. 16/848,830, filed on Apr. 14, 2020, now Pat. No. 11,101,108.
Application No. 16/848,830 is a continuation-in-part of application No. 17/142,069, filed on Jan. 5, 2021, now Pat. No. 11,636,998.
Application No. 17/231,923 is a continuation of application No. 16/524,926, filed on Jul. 29, 2019, now Pat. No. 10,991,553.
Application No. 16/524,926 is a continuation-in-part of application No. 16/523,840, filed on Jul. 26, 2019, now Pat. No. 10,892,140.
Application No. 16/721,396 is a continuation of application No. 16/524,967, filed on Jul. 29, 2019, now Pat. No. 10,811,230.
Application No. 16/524,967 is a continuation-in-part of application No. 16/523,840, filed on Jul. 26, 2019, now Pat. No. 10,892,140.
Application No. 16/722,115 is a continuation-in-part of application No. 16/523,840, filed on Jul. 26, 2019, now Pat. No. 10,892,140.
Application No. 16/523,840 is a continuation-in-part of application No. 16/178,565, filed on Nov. 1, 2018, now Pat. No. 10,607,814.
Application No. 16/848,830 is a continuation of application No. 16/525,357, filed on Jul. 29, 2019, now Pat. No. 10,659,019.
Application No. 16/525,357 is a continuation of application No. 16/523,840, filed on Jul. 26, 2019, now Pat. No. 10,892,140.
Application No. 17/142,069 is a continuation of application No. 16/524,950, filed on Jul. 29, 2019, now Pat. No. 10,892,141.
Application No. 16/524,950 is a continuation-in-part of application No. 16/523,840, filed on Jul. 26, 2019, now Pat. No. 10,892,140.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/717,523, filed on Aug. 10, 2018.
(60) Provisional application No. 62/789,523, filed on Jan. 8, 2019.
(60) Provisional application No. 62/789,526, filed on Jan. 8, 2019.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/717,523, filed on Aug. 10, 2018.
(60) Provisional application No. 62/789,523, filed on Jan. 8, 2019.
(60) Provisional application No. 62/789,526, filed on Jan. 8, 2019.
(60) Provisional application No. 62/717,523, filed on Aug. 10, 2018.
(60) Provisional application No. 62/774,078, filed on Nov. 30, 2018.
(60) Provisional application No. 62/789,523, filed on Jan. 8, 2019.
(60) Provisional application No. 62/789,526, filed on Jan. 8, 2019.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/789,523, filed on Jan. 8, 2019.
(60) Provisional application No. 62/789,526, filed on Jan. 8, 2019.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/717,523, filed on Aug. 10, 2018.
(60) Provisional application No. 62/789,523, filed on Jan. 8, 2019.
(60) Provisional application No. 62/789,526, filed on Jan. 8, 2019.
(60) Provisional application No. 62/717,637, filed on Aug. 10, 2018.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/717,523, filed on Aug. 10, 2018.
(60) Provisional application No. 62/789,523, filed on Jan. 8, 2019.
(60) Provisional application No. 62/789,526, filed on Jan. 8, 2019.
(60) Provisional application No. 62/711,406, filed on Jul. 27, 2018.
(60) Provisional application No. 62/711,464, filed on Jul. 27, 2018.
(60) Provisional application No. 62/711,334, filed on Jul. 27, 2018.
(60) Provisional application No. 62/711,457, filed on Jul. 27, 2018.
(60) Provisional application No. 62/711,347, filed on Jul. 27, 2018.
(60) Provisional application No. 62/711,467, filed on Jul. 27, 2018.
(60) Provisional application No. 62/711,468, filed on Jul. 27, 2018.
(60) Provisional application No. 62/717,523, filed on Aug. 10, 2018.
(60) Provisional application No. 62/789,523, filed on Jan. 8, 2019.
(60) Provisional application No. 62/789,526, filed on Jan. 8, 2019.

(51) Int. Cl. H01J 37/32; H01L 21/683; H01L 21/687; H02M 3/335; H03K 3/57; H03M 1/12; H05K 7/20

(52) U.S. Cl. CPC H01J 37/32146; H01J 37/32082; H01J 37/32091; H01J 37/32128; H01J 37/32174; H01J 37/32541; H01J 37/32568; H01J 37/32715; H01L 21/6833; H01L 21/68757; H02M 3/33523; H03K 3/57; H03M 1/12; H05K 7/20154; H05K 7/20172; H05K 7/20254; H05K 7/20272; H05K 7/20281; H05K 7/20509

(57) ABSTRACT

Embodiments provided herein generally include apparatus, e.g., plasma processing systems, and methods for the plasma processing of a substrate in a processing chamber. Some embodiments are directed to a waveform generator. The waveform generator generally includes a first voltage stage having: a first voltage source; a first switch; a ground reference; a transformer having a first transformer ratio, the first transformer comprising: a primary winding coupled to the first voltage source and the ground reference; and a secondary winding having a first end and a second end, wherein the first end is coupled to the ground reference, and the second end is configured to be coupled to a load through a common node; and a first diode coupled in parallel with the primary winding of the first transformer. The waveform generator generally also includes one or more additional voltage stages coupled to a load through the common node.

### CROSS-REFERENCE TO RELATED APPLICATIONS

### Background

Producing high voltage pulses with fast rise times and/or fast fall times is challenging. For instance, to achieve a fast rise time and/or a fast fall time (e.g., less than about 50 ns) for a high voltage pulse (e.g., greater than about 5 kV), the slope of the pulse rise and/or fall must be incredibly steep (e.g., greater than 1011 V/s). Such steep rise times and/or fall times are very difficult to produce especially in circuits driving a load with high capacitance. Such pulse may be especially difficult to produce using standard electrical components in a compact manner; and/or with pulses having variable pulse widths, voltages, and repetition rates; and/or within applications having capacitive loads such as, for example, a plasma.

Producing high voltage pulses with fast rise times and/or fast fall times is challenging. For instance, to achieve a fast rise time and/or a fast fall time (e.g., less than about 50 ns) for a high voltage pulse (e.g., greater than about 5 kV), the slope of the pulse rise and/or fall must be incredibly steep (e.g., greater than 1011 V/s). Such steep rise times and/or fall times are very difficult to produce especially in circuits driving a load with low capacitance. Such pulses may be especially difficult to produce using standard electrical components in a compact manner; and/or with pulses having variable pulse widths, voltages, and repetition rates; and/or within applications having capacitive loads such as, for example, a plasma.

In addition, wafer yield can determine whether a process was successful. Often, chips on the edge of a wafer may not be usable because of various defects that may occur at the edge of a wafer. These defects increase waste and decrease wafer yield.

### SUMMARY

A high voltage switch is disclosed comprising: a high voltage power supply having a voltage greater than 5 kV; a first switch module comprising: a first switch having a first voltage rating; a first transformer electrically coupled with a control voltage power source and electrically coupled with the first switch, providing a voltage less than the first voltage rating; and a first switch trigger electrically coupled with the first switch; a second switch module arranged in series with the first switch module, the second switch module comprising: a second switch having a second voltage rating; a second transformer electrically coupled with the control voltage power source and electrically coupled with the second switch, providing a voltage less than the second voltage rating; and a second switch trigger electrically coupled with the second switch, and an output configured to output switched pulses from the high voltage power supply where the output pulse voltage is greater than either the first switch voltage rating and/or the second switch voltage rating.

In some embodiments, the first switch trigger produces a trigger having a rise time less than about 20 ns. In some embodiments, the switched pulses have a frequency greater than about 40 kHz. In some embodiments, the switched pulses have a rise time less than about 75 ns. In some embodiments, the switched pulses have a fall time less than 100 ns. In some embodiments, the period of time where the first switch is closed while the second switch is open is less than 1 ms. In some embodiments, the stray capacitance of the high voltage switch is less than about 100 pF. In some embodiments, the stray inductance of either or both the first switch module or the second switch module less than 300 nH. In some embodiments, the control voltage power source provides AC line voltages and frequencies. In some embodiments, the control voltage power source provides 120 VAC at 60 Hz. In some embodiments, the any one of the secondary windings may have a stray capacitance with the primary of less than 100 pF.

In some embodiments, the high voltage switch may include a transformer core; and a plurality of primary windings wound around the transformer core, the plurality of primary windings being electrically coupled with the control voltage power source, wherein the first transformer comprises the transformer core, the plurality of primary windings, and a first plurality of secondary windings wound around the transformer core; and wherein the second transformer comprises the transformer core, the plurality of primary windings, and a second plurality of secondary windings wound around the transformer core.

A high voltage switch is disclosed comprising: a high voltage power supply providing power greater than about 5 kV; a control voltage power source; a plurality of switch modules arranged in series with respect to each other, each of the plurality of switch modules configured to switch power from the high voltage power supply, each of the plurality of switch modules comprising: a switch having a collector, an emitter, and a gate; a transformer electrically coupled with the control voltage power source and electrically or inductively coupled with the switch; and a gate trigger electrically coupled with the gate of the switch, wherein the switch is opened and closed based on a signal from the gate trigger; and an output configured to output a pulsed output signal having a voltage greater than the rating of any switch of the plurality of switches, a pulse width less than 2 μs, and at a pulse frequency greater than 10 KHz.

In some embodiments, the pulsed output signal includes pulses having a rate of rise greater than 1011 V/s. In some embodiments, the one or more switch modules of the plurality of switch modules produce less than 50 ns of jitter. In some embodiments, the output is coupled with a plasma load.

In some embodiments, the transformer comprises a transformer core and a secondary winding, wherein the average gap between the transformer core and the majority of the secondary winding is greater than 0.5 inches. In some embodiments, the transformer comprises a transformer core, a primary winding, and a secondary winding, wherein the average gap between the majority of the primary winding and the majority of the secondary winding is greater than 0.5 inches.

In some embodiments, each switch module is configured to switch at least 5 W of power. In some embodiments, the transformer comprises a transformer core and a secondary winding, wherein the secondary winding comprises a plurality of wires having a cross section with a width to thickness ratio less than 3. In some embodiments, the gate trigger comprises an isolated fiber optic trigger.

Some embodiments may include a method comprising: closing a first switch of a plurality of switches, the plurality of switches comprising n switches, while opening n−1 switches of the plurality of switches for a first plurality of time, wherein the plurality of switches are electrically coupled with a power supply that produces a high voltage V that is greater than 5 kV; outputting an output switched pulses with a voltage 1/nV on a load; closing a second switch of the plurality of switches while opening n−2 switches of the plurality of switches for a second period of time; outputting the output switched pulses with a voltage 2/nV on the load; closing a second-to-last switch of the plurality of switches while opening one switches of the plurality of switches for a second-to-last period of time; outputting the output switched pulses with a voltage n−1/nV on the load; closing an n^{th} switch of the plurality of switches for an n^{th} period of time; and outputting the output switched pulses with a voltage V on the load.

In some embodiments, one or more of the first period of time, the second period of time, the second-to-last period of time, and the n^{th} period of time are less than 100 ms. In some embodiments, the output switched pulses have a rise time less than about 20 ns. In some embodiments, the output switched pulses have a frequency greater than about 10 KHz.

Some embodiments of the invention include a spatially variable wafer bias system that may include a first high voltage pulser, a second high voltage pulser, a chamber, a first electrode, and a second electrode. In some embodiments, the first high voltage pulser may output a first plurality of pulses having a first voltage greater than about 1 kV, a first pulse width less than about 1 μs, and a first pulse repletion frequency greater than about 20 kHz. In some embodiments, the second high voltage pulser may output a second plurality of pulses having a second voltage greater than about 1 kV, a second pulse width less than about 1 μs, and a second pulse repletion frequency greater than about 20 kHz. In some embodiments, the first electrode may be disposed within the chamber and electrically coupled with the first high voltage pulser; and the second electrode may be disposed within the chamber adjacent with the first electrode and electrically coupled with the second high voltage pulser.

In some embodiments, the chamber includes either or both a wafer and a plasma may be capacitively coupled with the first electrode and the second electrode with a capacitance between 10 pF and 1 μF.

In some embodiments, an electric field across the surface of the wafer may be uniform by less than 25%, 20%, 15%, 10%, 5% or 2% or better using a first nanosecond pulser and a second nanosecond pulser.

In some embodiments, the capacitance between the first electrode and a corresponding portion of the wafer is greater than 100 pF; and the capacitance between the second electrode and a corresponding portion of the wafer is greater than 100 pF.

In some embodiments, the chamber may include a plasma of ions that are accelerated onto a wafer.

In some embodiments, the first high voltage pulser produces an electrode voltage on the first electrode that is greater than about 1 kV, and the second high voltage pulser produces an electrode voltage on the second electrode that is greater than about 1 kV. In some embodiments, the ratio of the first voltage relative to the second voltage is less than two to one or vice versa.

In some embodiments, either or both the first electrode and the second electrode are axially symmetric.

In some embodiments, the first electrode has a first planar surface, and the second electrode has a second planar surface such that the second planar surface area is about 25% of the total of the first planar surface and the second planar surface.

In some embodiments, both the first the first high voltage pulser and the second high voltage pulser comprise a resistive output stage. In some embodiments, both the first high voltage pulser and the second high voltage pulser comprise an energy recovery circuit.

In some embodiments, the parameters of the first plurality of pulses are controlled independently of the parameters of the second plurality of pulses. In some embodiments, the first pulse repletion frequency and the second pulse repetition frequency are in phase with respect of each other.

In some embodiments, the capacitance between the first electrode and the second electrode is less than about 10 nF.

In some embodiments, the first electrode comprises: a disc shape, a central axis, and an outer diameter. In some embodiments, the second electrode comprises: a disc shape with a central aperture, the first electrode disposed within the central aperture; a central axis aligned with the central axis of the first electrode, an aperture diameter, and an outer diameter.

Some embodiments of the invention include a spatially variable wafer bias system that may include a wafer platform, a first electrode, a second electrode, a first high voltage pulser, and a second high voltage pulser. In some embodiments, the first electrode may include a disc shape, a central axis, and an outer diameter. In some embodiments, the second electrode may include a disc shape with a central aperture, the first electrode disposed within the central aperture; a central axis aligned with the central axis of the first electrode, an aperture diameter, and an outer diameter. In some embodiments, the first high voltage pulser may be electrically coupled with the first electrode, and the first high voltage pulser may produce pulses greater than 5 kV with a pulse repetition rate greater than 10 kHz. In some embodiments, the second high voltage pulser may be electrically coupled with the second electrode, and the second high voltage pulser may produce pulses greater than 5 kV with a pulse repetition rate greater than 10 KHz.

In some embodiments, the second high voltage pulser provides pulses with an amplitude that is a fraction of the amplitude of the pulses provided by the first high voltage pulser. In some embodiments, the second high voltage pulser provides pulses with a pulse repetition frequency that is a fraction of the pulse repetition frequency of the pulses provided by the first high voltage pulser.

In some embodiments, the spatially variable wafer bias system may also include a first resistive output stage coupled with the first high voltage pulser and the first electrode; and a second resistive output stage coupled with the second high voltage pulser and the second electrode. In some embodiments, the spatially variable wafer bias system may also include a bias compensation circuit coupled with the first high voltage pulser and the first electrode.

In some embodiments, the spatially variable wafer bias system may also include a ring of insulating material disposed between the first electrode and the second electrode. In some embodiments, the wafer platform comprises a dielectric material or a ceramic material. In some embodiments, the wafer platform has an outer diameter that is substantially similar to the outer diameter of the second electrode.

Some embodiments may include a method that may include pulsing a first high voltage pulser coupled with a first electrode in a plasma chamber, the first high voltage pulser pulsing at a first voltage greater than about 1 kV, with a first pulse repetition frequency greater than about 20 kHz, and with a first pulse width; pulsing a second high voltage pulser coupled with a second electrode in the plasma chamber, the second high voltage pulser pulsing at a second voltage greater than about 1 kV, with a second pulse repetition frequency greater than about 20 kHz, and with a second pulse width. In some embodiments, the first electrode and the second electrode are disposed beneath a wafer. The method may also include measuring a parameter corresponding with a physical phenomenon occurring within the plasma chamber (e.g., chuck voltage, electrode voltage, electric filed uniformity, ion current, etc.). And adjusting at least one of the second voltage, the second pulse repetition frequency, and the second pulser width an amount based on the measured parameter.

In some embodiments, the voltages or currents measured at various locations within the plasma chamber correspond with the uniformity of the electric field across a surface of the wafer.

In some embodiments, the voltages or currents measured at various locations within the plasma chamber correspond with the uniformity of the ion current across a surface of the wafer.

In some embodiments, the parameter is the current flowing through a resistor in either a resistive output stage or an energy recovery circuit.

Some embodiments of the invention include a spatially variable wafer bias system. For example, a wafer bias system may include a system comprising: a disc-shaped wafer platform; a first electrode having a disc shape disposed proximate and aligned with the wafer platform; a second electrode having a disc shape and central aperture disposed proximate and aligned with the wafer platform such that the first electrode is disposed within the central aperture; a first high voltage pulser electrically coupled with the first electrode; and a second high voltage pulser electrically coupled with the second electrode.

In some embodiments, the second high voltage pulser provides pulses with an amplitude that is a fraction of the amplitude of the pulses provided by the first high voltage pulser. The fraction, for example, may include 50%, 75%, 100%, 125%, 150%, 200%, etc.

In some embodiments, the system further includes a first resistive output stage coupled with the first high voltage pulser and the first electrode.

In some embodiments, the system further includes a second resistive output stage coupled with the second high voltage pulser and the second electrode.

In some embodiments, the system further includes a bias capacitor coupled with the first high voltage pulser and the first electrode.

In some embodiments, the system further includes a bias capacitor coupled with the first high voltage pulser and the second electrode.

In some embodiments, the first high voltage pulser comprises one or more nanosecond pulsers. In some embodiments, the second high voltage pulser comprises one or more nanosecond pulsers.

Some embodiments include a plasma deposition system comprising a wafer platform, a first electrode, a second electrode, a first high voltage pulser, and a second high voltage pulser. In some embodiments, the second electrode may be disposed beneath the wafer platform. In some embodiments, the second electrode can include a disc shape with a central aperture; a central axis, an aperture diameter, and an outer diameter. In some embodiments, the first electrode may be disposed beneath the wafer platform and within the central aperture of the second electrode. In some embodiments, the first electrode can include a disc shape, a central axis, and an outer diameter. In some embodiments, the first high voltage pulser can be electrically coupled with the first electrode. In some embodiments, the first high voltage pulser can produce pulses greater than 5 kV with a pulse repetition rate greater than 10 kHz. In some embodiments, the second high voltage pulser can be electrically coupled with the second electrode. In some embodiments, the second high voltage pulser can produce pulses greater than 5 kV with a pulse repetition rate greater than 10 kHz.

Some embodiments include a plasma deposition system comprising a wafer platform having a first platform region and a second platform region; a first electrode disposed beneath the first platform region of the wafer platform; a second electrode disposed beneath the second platform region of the wafer platform; a first high voltage pulser electrically coupled with the first electrode, the first high voltage pulser producing pulses greater than 2 kV with a pulse repetition rate greater than 10 kHz; and a second high voltage pulser electrically coupled with the second electrode, the second high voltage pulser producing pulses greater than 2 kV with a pulse repetition rate greater than 10 KHz.

In some embodiments, the second high voltage pulser provides pulses with an amplitude that is a fraction of the amplitude of the pulses provided by the first high voltage pulser.

In some embodiments, the second high voltage pulser provides pulses with a pulse repetition frequency that is a fraction of the pulse repetition frequency of the pulses provided by the first high voltage pulser.

In some embodiments, the first high voltage pulser or the second high voltage pulser comprises one or more nanosecond pulsers.

In some embodiments, the first high voltage pulser or the second high voltage pulser comprises one or more high voltage switches.

Some embodiments include a system comprising: a wafer platform; a plurality of electrodes disposed beneath the wafer platform; and a plurality of high voltage pulsers electrically coupled with a respective one of the plurality of electrodes, each of the plurality of high voltage pulsers producing pulses greater than 5 kV with a pulse repetition rate greater than 10 kHz. In some embodiments, each of the plurality of electrodes are separated from each other with insulation. In some embodiments, each of the plurality of high voltage pulsers produce pulses with either or both different voltages or pulse repetition rates.

These illustrative embodiments are mentioned not to limit or define the disclosure, but to provide examples to aid understanding thereof. Additional embodiments are discussed in the Detailed Description, and further description is provided there. Advantages offered by one or more of the various embodiments may be further understood by examining this specification or by practicing one or more embodiments presented.

### BRIEF DESCRIPTION OF THE DRAWINGS

These and other features, aspects, and advantages of the present disclosure are better understood when the following Detailed Description is read with reference to the accompanying drawings.

FIG. 1 is a block diagram of a high voltage switch with isolated power according to some embodiments.

FIG. 2 is an image of high voltage switch according to some embodiments.

FIG. 3 illustrates an isolation transformer arrangement according to some embodiments.

FIG. 4 illustrates an isolation transformer arrangement according to some embodiments.

FIG. 5A illustrates a cross-section of a secondary winding according to some embodiments.

FIG. 5B illustrates a cross-section of a secondary winding according to some embodiments.

FIG. 6A illustrates an isolation transformer according to some embodiments.

FIG. 6B illustrates an end view of an isolation transformer according to some embodiments

FIG. 7 is an image of an isolation transformer according to some embodiments.

FIG. 8 illustrates four 500 ns waveforms from a high voltage switch that includes sixteen IGBT switch modules.

FIG. 9 illustrates four 500 ns waveforms from a high voltage switch that includes sixteen SiC MOSFET switch modules.

FIG. 10A illustrates a 10 μs, 10 kV waveform from a high voltage switch that includes sixteen IGBT switch modules with a 50 ohm load.

FIG. 10B illustrates a 500 kHz, 12 kV waveform with a 1 μs pulse width from a high voltage switch that includes sixteen IGBT switch modules with a 200 ohm load.

FIG. 10C illustrates a 500 ns, 15 kV waveform from a high voltage switch that includes sixteen IGBT switch modules with a 500 ohm load.

FIG. 11 is flowchart of a method for producing a multilevel waveform using a high voltage switch according to some embodiments.

FIG. 12A illustrates an upward pulse-step waveform produced from a high voltage switch according to some embodiments.

FIG. 12B illustrates a downward pulse-step waveform produced from a high voltage switch according to some embodiments.

FIG. 13 is a circuit diagram of a high voltage etch system according to some embodiments.

FIG. 14 shows example waveforms produced by the high voltage etch system.

FIG. 15 is a circuit diagram of a high voltage etch system according to some embodiments.

FIG. 16 is a circuit diagram of a nanosecond pulser according to some embodiments.

FIG. 17 shows example waveforms produced by the nanosecond pulser.

FIG. 18 is another example of a nanosecond pulser according to some embodiments.

FIG. 19A and FIG. 19B are block diagrams of a spatially variable wafer bias power system according to some embodiments.

FIG. 20 is a block diagram of a spatially variable wafer bias power system according to some embodiments.

FIG. 21 is a schematic of a spatially variable wafer bias system according to some embodiments.

FIG. 22 is a schematic of a spatially variable wafer bias system according to some embodiments.

FIG. 23 is a schematic of a spatially variable wafer bias system according to some embodiments.

FIG. 24 shows an illustrative computational system for performing functionality to facilitate implementation of embodiments described herein.

### DETAILED DESCRIPTION

A high voltage switch is disclosed. A high voltage switch may include a high voltage power supply, a plurality of switch modules arranged in series, and an output configured to output switched pulses from the power supply with voltages greater than 5 kV, with rise times less than about 100 ns, a rise greater than 1011 V/s, a pulse width less than 2 μs, and/or frequencies greater than about 10 kHz. In some embodiments, the plurality of switches may be trigged by respective gate driver circuits that are electrically isolated from other components. In some embodiments, each switch module may include a switch (e.g., a solid-state switch) having a collector, an emitter, and a gate; or a switch having drain, source, and gate; and/or a snubber circuit.

In some embodiments, the high voltage switch may include a plurality of solid-state switches arranged to collectively switch voltages from about 10 kV to about 400 kV. In some embodiments, the high voltage switch may switch with frequencies up to about 2,000 kHz. In some embodiments, the high voltage switch may provide single pulses of varying pulse widths from about 50 seconds down to about 1 nanosecond. In some embodiments, the high voltage switch may switch at frequencies greater than about 10 kHz. In some embodiments, the high voltage switch may operate with rise times less than about 20 ns. In some embodiments, the high voltage switch may include fiber optic and/or control voltage isolation. In some embodiments, a plurality of high voltage switches may be electrically coupled together in parallel.

As used throughout this document, the term “high voltage” may include a voltage greater than about 1 kV, 10 kV, 20 kV, 50 kV, 100 kV, 1,000 kV, etc.; the term “high frequency” may be a frequency greater than about 1 kHz, 10 kHz, 100 kHz, 200 kHz, 500 kHz, 1 MHz, etc.; the term “high repetition rate” may be a rate greater than about 1 kHz, 10 kHz, 100 kHz, 200 kHz, 500 kHz, 1 MHz, etc., the term “fast rise time” may include a rise time less than about 1 ns, 10 ns, 50 ns, 100 ns, 250 ns, 500 ns, 1,000 ns, etc.; the term “fast fall time” may include a fall time less than about 1 ns, 10 ns, 50 ns, 100 ns, 250 ns, 500 ns, 1,000 ns, etc.; the term “low capacitance” may include capacitance less than about 1.0 pF, 10 pF, 100 pF, 1,000 pF, etc.; the term “low inductance” may include inductance less than about 10 nH, 100 nH, 1,000 nH, 10,000 nH, etc.; and the term short pulse width may include pulse widths less than about 10,000 ns, 1,000 ns, 500 ns, 250 ns, 100 ns, 20 ns, etc.

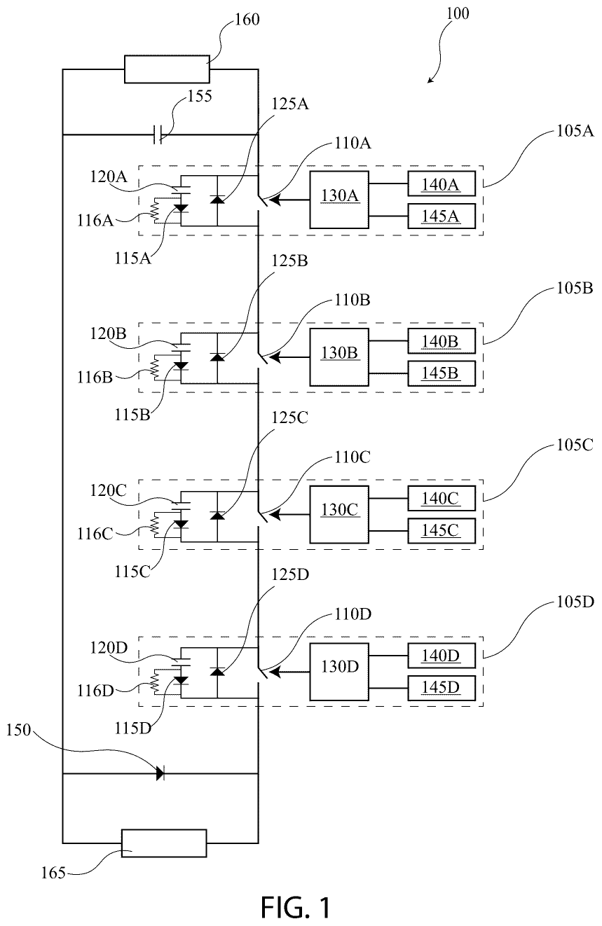

FIG. 1 is a block diagram of a high voltage switch 100 with isolated power according to some embodiments. The high voltage switch 100 may include a plurality of switch modules 105 (collectively or individually 105, and individually 105A, 105B, 105C, and 105D) that may switch voltage from a high voltage source 160 with fast rise times and/or high frequencies and/or with variable pulse widths. Each switch module 105 may include a switch 110 such as, for example, a solid-state switch.

In some embodiments, the switch 110 may be electrically coupled with a gate driver circuit 130 that may include a power supply 140 and/or an isolated fiber trigger 145 (also referred to as a gate trigger or a switch trigger). For example, the switch 110 may include a collector, an emitter, and a gate (or a drain, a source, and a gate) and the power supply 140 may drive the gate of the switch 110 via the gate driver circuit 130. The gate driver circuit 130 may, for example, be isolated from the other components of the high voltage switch 100.

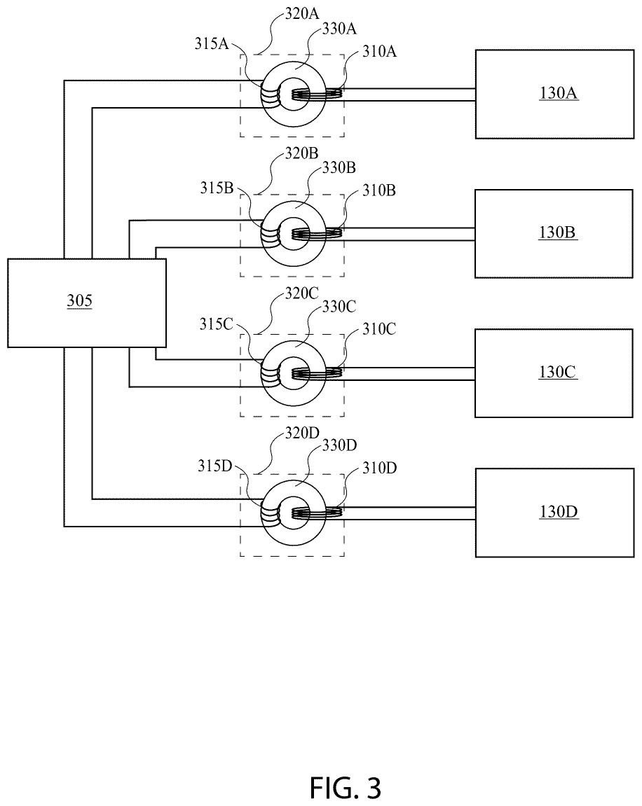

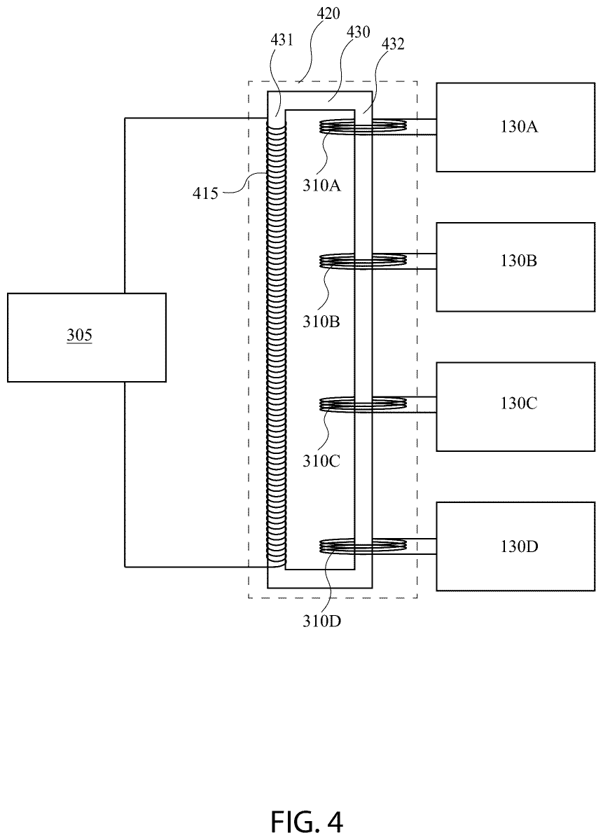

In some embodiments, the power supply 140 may be isolated, for example, using an isolation transformer. The isolation transformer may include a low capacitance transformer. The low capacitance of the isolation transformer may, for example, allow the power supply 140 to charge on fast time scales without requiring significant current. The isolation transformer may have a capacitance less than, for example, about 100 pF. As another example, the isolation transformer may have a capacitance less than about 30-100 pF. In some embodiments, the isolation transformer may provide voltage isolation up to 5 kV, 10 kV, 25 kV, 50 kV, etc. An example arrangement of isolation transformers is shown in FIG. 3 and a single isolation transformer is shown in FIG. 4.

In some embodiments, the isolation transformer may have a low stray capacitance. For example, the isolation transformer may have a stray capacitance less than about 1,000 pF, 100 pF, 10 pF, etc. In some embodiments, low capacitance may minimize electrical coupling to low voltage components (e.g., the source of the input control power) and/or may reduce EMI generation (e.g., electrical noise generation). In some embodiments, the transformer stray capacitance of the isolation transformer may include the capacitance measured between the primary winding and secondary winding.

In some embodiments, the isolation transformer may be a DC-to-DC converter or an AC to DC transformer. In some embodiments, the transformer, for example, may include a 110 V AC transformer. Regardless, the isolation transformer can provide isolated power from other components in the high voltage switch 100. In some embodiments, the isolation may be galvanic, such that no conductor on the primary side of the isolation transformer passes through or makes contact with any conductor on the secondary side of the isolation transformer.

In some embodiments, the transformer may include a primary winding that may be wound and/or wrapped tightly around the transformer core. In some embodiments, the primary winding may include a conductive sheet that is wrapped around the transformer core. In some embodiments, the primary winding may include one or more windings.

In some embodiments, a secondary winding may be wound around the core as far from the core as possible. For example, the bundle of windings comprising the secondary winding may be wound through the center of the aperture in the transformer core. In some embodiments, the secondary winding may include one or more windings. In some embodiments, the bundle of wires comprising the secondary winding may include a cross section that is circular or square, for example, to minimize stray capacitance. In some embodiments, an insulator (e.g., oil or air) may be disposed between the primary winding, the secondary winding, and/or the transformer core.

In some embodiments, keeping the secondary winding far from the transformer core may have some benefits. For example, it may reduce the stray capacitance between the primary side of the isolation transformer and secondary side of the isolation transformer. As another example, it may allow for high voltage standoff between the primary side of the isolation transformer and the secondary side of the isolation transformer, such that corona and/or breakdown is not formed during operation.

In some embodiments, spacings between the primary side (e.g., the primary windings) of the isolation transformer and the secondary side of the isolation transformer (e.g., the secondary windings) can be about 0.1″, 0.5″, 1″, 5″, or 10″. In some embodiments, typical spacings between the core of the isolation transformer and the secondary side of the isolation transformer (e.g., the secondary windings) can be about 0.1″, 0.5″, 1″, 5″, or 10″. In some embodiments, the gap between the windings may be filled with the lowest dielectric material possible such as, for example, vacuum, air, any insulating gas or liquid, and/or solid materials with a relative dielectric constant less than 3.

In some embodiments, the power supply 140 may include any type of power supply that can provide high voltage standoff (isolation) and/or have low capacitance (e.g., less than about 1,000 pF, 100 pF, 10 pF, etc.). In some embodiments, the control voltage power source may supply 120 V AC or 240 V AC at 60 Hz.

In some embodiments, each power supply 140 may be inductively electrically coupled with a single control voltage power source (e.g., as shown in FIG. 3 or FIG. 4). For example, the power supply 140A may be electrically coupled with the power source via a first transformer; the power supply 140B may be electrically coupled with the power source via a second transformer; the power supply 140C may be electrically coupled with the power source via a third transformer; and the power supply 140D may be electrically coupled with the power source via a fourth transformer. Any type of transformer, for example, may be used that can provide voltage isolation between the various power supplies.

In some embodiments, the first transformer, the second transformer, the third transformer, and the fourth transformer may comprise different secondary winding around a core of a single transformer (e.g., as shown in FIG. 4). For example, the first transformer may comprise a first secondary winding, the second transformer may comprise a second secondary winding, the third transformer may comprise a third secondary winding, and the fourth transformer may comprise a fourth secondary winding. Each of these secondary winding may be wound around the core of a single transformer. In some embodiments, the first secondary winding, the second secondary winding, the third secondary winding, the fourth secondary winding, and/or the primary winding may comprise a single winding or a plurality of windings wound around the transformer core.

In some embodiments, the power supply 140A, the power supply 140B, the power supply 140C, and/or the power supply 140D may not share a return reference ground and/or a local ground.

The isolated fiber trigger 145, for example, may also be isolated from other components of the high voltage switch 100. The isolated fiber trigger 145 may include a fiber optic receiver that allows each switch module 105 to float relative to other switch modules 105 and/or the other components of the high voltage switch 100, and/or, for example, while allowing for active control of the gates of each switch module 105.

In some embodiments, return reference grounds and/or local grounds and/or common grounds for each switch module 105, for example, may be isolated from one another, for example, using an isolation transformer such as, for example, the transformer arrangement shown in either FIG. 3 or FIG. 4.

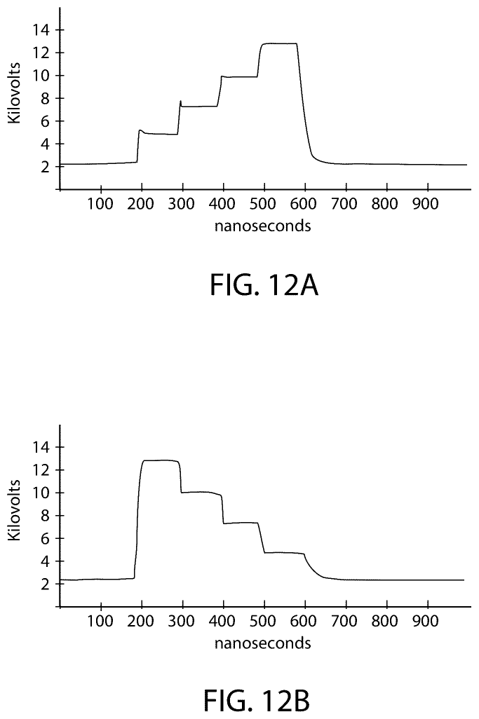

Electrical isolation of each switch module 105 from common ground, for example, can allow multiple switches to be arranged in a series configuration for cumulative high voltage switching. In some embodiments, some lag in switch module timing may be allowed or designed (e.g., see FIG. 12A and FIG. 12B). For example, each switch module 105 may be configured or rated to switch 1 kV, each switch module may be electrically isolated from each other, and/or the timing of closing each switch module 105 may not need to be perfectly aligned for a period of time defined by the capacitance of the snubber capacitor and/or the voltage rating of the switch.

In some embodiments, electrical isolation may provide many advantages. One possible advantage, for example, may include minimizing switch to switch jitter and/or allowing for arbitrary switch timing. For example, each switch 110 may have switch transition jitters less than about 500 ns, 50 ns, 20 ns, 5 ns, etc.

In some embodiments, electrical isolation between two components (or circuits) may imply extremely high resistance between two components and/or may imply a small capacitance between the two components.

Each switch 110 may include any type of silicon switching device such as, for example, an IGBT, a MOSFET, a SiC MOSFET, SiC junction transistor, FETs, SiC switches, GaN switches, photoconductive switch, etc. The switch 110, for example, may be able to switch high voltages (e.g., voltages greater than about 1 kV), with high frequency (e.g., greater than 1 kHz), at high speeds (e.g., a repetition rate greater than about 500 kHz) and/or with fast rise times (e.g., a rise time less than about 25 ns) and/or with long pulse lengths (e.g., greater than about 10 ms). In some embodiments, each switch may be individually rated for switching 1,200 V-1,700 V, yet in combination can switch greater than 4,800 V-6,800 V (for four switches). Switches with various other voltage ratings may be used.

There may be some advantages to using a large number of lower voltage switches rather than a few higher voltage switches. For example, lower voltage switches typically have better performance: lower voltage switches may switch faster, may have faster transition times, and/or may switch more efficiently than high voltage switches. However, the greater the number of switches the greater the timing issues that may be required.

The high voltage switch 100 shown in FIG. 1 includes four switch modules 105. While four are shown in this figure, any number of switch modules 105 may be used such as, for example, eight, twelve, sixteen, twenty, twenty-four, etc. For example, if each switch in each switch module 105 is rated at 1200 V, and sixteen switches are used, then the high voltage switch can switch up to 19.2 kV. As another example, if each switch in each switch module 105 is rated at 1700 V, and sixteen switches are used, then the high voltage switch can switch up to 27.2 kV.

In some embodiments, the high voltage switch 100 may include a fast capacitor 155. The fast capacitor 155, for example, may include one or more capacitors arranged in series and/or in parallel. These capacitors may, for example, include one or more polypropylene capacitors. The fast capacitor 155 may store energy from the high voltage source 160.

In some embodiments, the fast capacitor 155 may have low capacitance. In some embodiments, the fast capacitor 155 may have a capacitance value of about 1 μF, about 5 μF, between about 1 μF and about 5 μF, between about 100 nF and about 1,000 nF etc.

In some embodiments, the high voltage switch 100 may or may not include a crowbar diode 150. The crowbar diode 150 may include a plurality of diodes that may, for example, be beneficial for driving inductive loads. In some embodiments, the crowbar diode 150 may include one or more Schottky diodes such as, for example, a silicon carbide Schottky diode. The crowbar diode 150 may, for example, sense whether the voltage from the switches of the high voltage switch is above a certain threshold. If it is, then the crowbar diode 150 may short the power from switch modules to ground. The crowbar diode, for example, may allow an alternating current path to dissipate energy stored in the inductive load after switching. This may, for example, prevent large inductive voltage spikes. In some embodiments, the crowbar diode 150 may have low inductance such as, for example, 1 nH, 10 nH, 100 nH, etc. In some embodiments, the crowbar diode 150 may have low capacitance such as, for example, 100 pF, 1 nF, 10 nF, 100 nF, etc.

In some embodiments, the crowbar diode 150 may not be used such as, for example, when the load 165 is primarily resistive.

In some embodiments, each gate driver circuit 130 may produce less than about 1000 ns, 100 ns, 10.0 ns, 5.0 ns, 3.0 ns, 1.0 ns, etc. of jitter. In some embodiments, each switch 110 may have a minimum switch on time (e.g., less than about 10 μs, 1 μs, 500 ns, 100 ns, 50 ns, 10, 5 ns, etc.) and a maximum switch on time (e.g., greater than 25 s, 10 s, 5 s, 1 s, 500 ms, etc.).

In some embodiments, during operation each of the high voltage switches may be switched on and/or off within 1 ns of each other.

In some embodiments, each switch module 105 may have the same or substantially the same (+5%) stray inductance. Stray inductance may include any inductance within the switch module 105 that is not associated with an inductor such as, for example, inductance in leads, diodes, resistors, switch 110, and/or circuit board traces, etc. The stray inductance within each switch module 105 may include low inductance such as, for example, an inductance less than about 100 nH, 10 nH, 1 nH, etc. The stray inductance between each switch module 105 may include low inductance such as, for example, an inductance less than about 300 nH, 100 nH, 10 nH, 1 nH, etc.

In some embodiments, each switch module 105 may have the same or substantially the same (+5%) stray capacitance. Stray capacitance may include any capacitance within the switch module 105 that is not associated with a capacitor such as, for example, capacitance in leads, diodes, resistors, switch 110 and/or circuit board traces, etc. The stray capacitance within each switch module 105 may include low capacitance such as, for example, less than about 1,000 pF, 100 pF, 10 pF, etc. The stray capacitance between each switch module 105 may include low capacitance such as, for example, less than about 1,000 pF, 100 pF, 10 pF, etc.

Imperfections in voltage sharing can be addressed, for example, with a passive snubber circuit (e.g., the snubber diode 115, the snubber capacitor 120, and/or the freewheeling diode 125). For example, small differences in the timing between when each of the switches 110 turn on or turn off or differences in the inductance or capacitances may lead to voltage spikes. These spikes can be mitigated by the various snubber circuits (e.g., the snubber diode 115, the snubber capacitor 120, and/or the freewheeling diode 125). This mitigation can allow for stepwise high voltage waveforms as demonstrated in the stepping waveforms shown in FIGS. 12A and 12B.

A snubber circuit, for example, may include a snubber diode 115, a snubber capacitor 120, a snubber resistor 116, and/or a freewheeling diode 125. In some embodiments, the snubber circuit may be arranged together in parallel with the switch 110. In some embodiments, the snubber capacitor 120 may have low capacitance such as, for example, a capacitance less than about 100 pF.

In some embodiments, the high voltage switch 100 may be electrically coupled with or include a resistive load 165. The resistive load 165, for example, may have a resistance from 50 ohms to 500 ohms. Alternatively or additionally, the load 165 may be an inductive load.

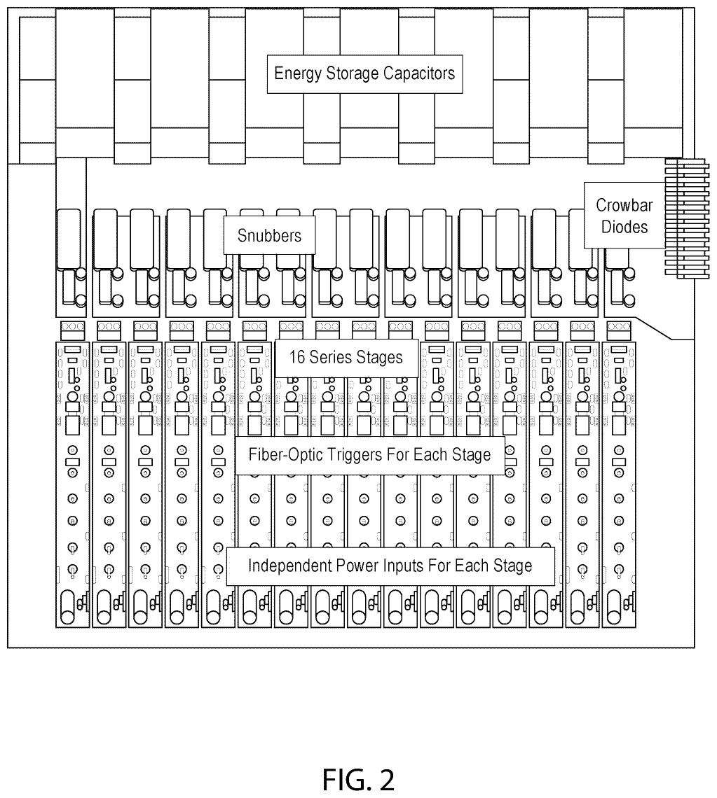

FIG. 2 is an image of an example high voltage switch according to some embodiments. In this example, the high voltage switch includes a plurality of independent power inputs (e.g., power supplies 140), a plurality of fiber-optic triggers (e.g., isolated fiber trigger 145), a plurality of switch stages (e.g., switches 110), a plurality of snubber components (e.g., the snubber diode 115, the snubber capacitor 120, and/or the freewheeling diode 125), a plurality of crowbar diodes (e.g., crowbar diode 150), and a plurality of energy storage capacitors (e.g., fast capacitor 155).

FIG. 3 illustrates a block diagram of an arrangement of isolation transformers according to some embodiments. In this embodiment, a plurality of isolation transformers 320 (collectively or individually 320, and individually 320A, 320B, 320C, 320D) may be electrically coupled with a control voltage power source 305 and a plurality of gate driver circuits 130. In some embodiments, the control voltage power source 305 may include any power supply that can provide AC or DC power to the isolation transformers 320 such as, for example, 120 V AC or 240 V AC at 60 Hz. In some embodiments, the control voltage power source 305 may provide power greater than 1 W, 10 W, 100 W, for example. In some embodiments, the control voltage power source 305 may provide a voltage greater than 10 V, or 100 V, for example. In some embodiments, control voltage power source 305 may comprise one or more power supplies.

Each of the plurality of isolation transformers 320, may include a transformer core 330 (collectively or individually 330, and individually 330A, 330B, 330C, 330D), a primary winding 315 (collectively or individually 315, and individually 315A, 315B, 315C, 315D), and/or a secondary winding 310 (collectively or individually 310, and individually 310A, 310B, 310C, 310D). Any number of isolation transformers 320 may be used. The control voltage power source 305 may be electrically coupled with each primary winding 315.

Each primary winding 315 may include any number of individual windings of wire that are wound about a respective one of the transformer cores 330. In some embodiments, the primary winding 315 may be tightly wound around the transformer core 330. In some embodiments, the primary winding 315 may include a conductive sheet that is wound, wrapped, or draped around the transformer core but is not electrically coupled with the transformer core 330.

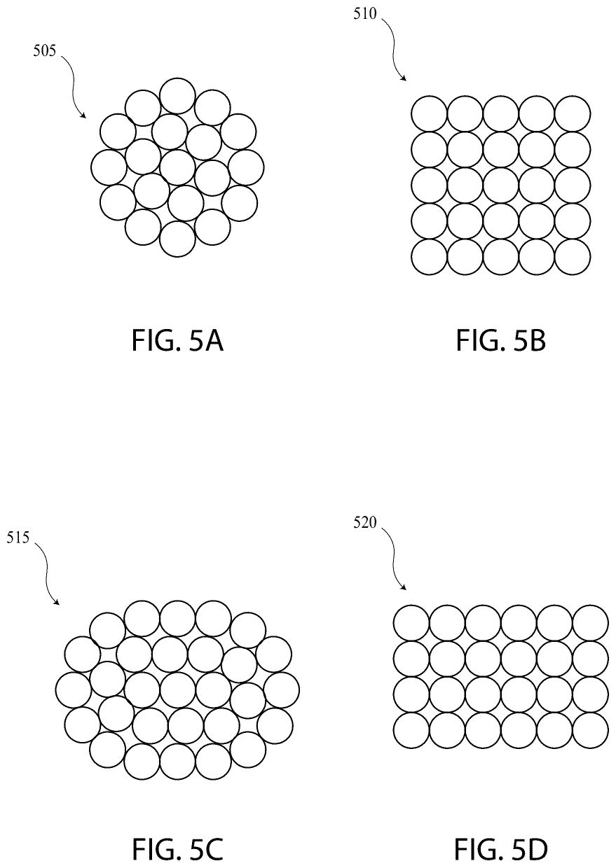

In some embodiments, the secondary winding 310 may be wound around the transformer core 330 with as much space between the transformer core 330 and the secondary winding 310 as possible. For example, the secondary winding 310 may pass through the center of the aperture in the transformer core 330. In some embodiments, the secondary winding 310 may comprise a bundle of wires with a small surface area such as, for example, a bundle that has a circular cross-section (see FIG. 5A), a square cross-section (see FIG. 5B), an elliptical cross-section (see FIG. 5C), and/or a rectangular cross-section (See FIG. 5D). Various other cross-sections may be used. The small surface area and/or the distance from the center of the transformer core may, for example, result in a lower capacitance.

In some embodiments, the secondary winding 310 may be arranged relative to the primary winding 315 with as much space between the primary winding 315 and the secondary winding 310 as possible. In some embodiments, the primary winding 315 may comprise a bundle of wires with a small surface area such as, for example, a bundle that has a circular cross-section (see FIG. 5A), square cross-section (see FIG. 5B), an elliptical cross-section (see FIG. 5C), and/or a rectangular cross-section (See FIG. 5D). Various other bundle cross-sections may be used. The small surface area and/or the distance from the center of the transformer core may, for example, result in a lower capacitance.

Each of the transformer cores 330, for example, may be a toroid-shaped core, a square-shaped core, a rectangular-shaped core, or a rod-shaped core. Each of the transformer cores 330 may be comprised of iron, ferrite, soft ferrite, MnZn, NiZn, hard ferrite, powder, nickel-iron alloys, amorphous metal, glassy metal, or some combination thereof.

In some embodiments, each of the isolation transformers 320 may have an effective/equivalent capacitance (e.g., the stray capacitance between the primary winding and the secondary winding) of less than about 100 pF, 10 pF, 1 pF, etc.

In some embodiments, each secondary winding 310 may include a wire wound around a respective one of the transformer cores 330. In this example, for each secondary winding 310, the ratio of the number of each winding around the core to the number of primary winding 315 wound around the core may determine the voltage delivered from each of the secondary winding 310. In some embodiments, each secondary winding 310 may be electrically coupled with a corresponding gate driver circuit 130.

In some embodiments, a ground of the control voltage power source 305 is not electrically coupled with a common ground associated with each or any secondary winding 310 and/or a ground associated with each or any of the gate drivers 130. As another example, the common ground of the control voltage power source 305, the ground of each secondary winding 310 and/or the common ground associated with each of the gate drivers 130 may float relative to each other.

FIG. 4 illustrates a block diagram of an isolation transformer arrangement according to some embodiments. The isolation transformer 420 may be electrically coupled with a control voltage power source 305 and/or a plurality of gate driver circuits 130. The control voltage power source 305 may include any power supply that can provide AC power to the isolation transformer 420. control voltage power source 305 control voltage power source 305

The isolation transformer 420 may include a transformer core 430, a primary winding 415, and/or a plurality of secondary windings 310.

In this example, the transformer core 430 comprises a rectangular shaped core with an interior aperture having a first core leg 431 and a second core leg 432. The transformer core 430 may be comprised of iron, ferrite, soft ferrite, MnZn, NiZn, hard ferrite, powder, nickel-iron alloys, amorphous metal, glassy metal, or some combination thereof.

The control voltage power source 305 may be electrically coupled with the primary winding 415. The primary winding 415 may include wires wound around the first core leg 431 of the transformer core 430. In some embodiments, the primary winding 415 may be wound and/or wrapped tightly around the first core leg 431 of the transformer core 430. In some embodiments, the primary winding 415 may include a conductive sheet that is draped around the first core leg 431 of the transformer core 430. The primary winding may be wrapped around any of the legs or sides of the transformer core 430, and multiple primaries may be used in parallel.

In some embodiments, the isolation transformer 420 may have an effective/equivalent capacitance of less than about 100 pF, 10 pF, 1 pF, etc.

In some embodiments, a plurality of different secondary winding 310 may be wound around the second core leg 432 of the transformer core 430 or any leg or portion of the transformer core 430. Each secondary winding 310 may include a wire that is wound a number of times around a transformer core 430. In this example, four different secondary winding 310 are represented. Any number of secondary windings may be included. For each secondary winding, the ratio of the number of each winding around the core to the number of primary winding 415 wound around the core may determine the voltage delivered from each of the secondary winding 310. In some embodiments, each secondary winding 310 may be electrically coupled with a corresponding gate driver circuit 130. As shown in FIG. 4, four secondary winding 310 are electrically coupled with a respective one of four different gate driver circuit 130.

In some embodiments, the secondary winding 310 may be wound around the second core leg 432 of the transformer core 430 with as much space between the transformer core 330 and the secondary winding 310 as possible and/or with as much space between the primary winding 415 and the secondary winding 310 as possible. For example, the secondary winding 310 may pass through the center of the aperture in the transformer core 430. In some embodiments, the secondary winding 310 may comprise a bundle of wires with a small surface area such as, for example, a bundle that has a circular cross-section (see FIG. 5A), a square cross-section (see FIG. 5B), an elliptical cross-section (see FIG. 5C), and/or a rectangular cross-section (See FIG. 5D). As another example, the secondary winding may include a bundle of wires in a rectangular cross-section (see FIG. 5D) where the effective width is less than twice the effective thickness, or an elliptical cross section (see FIG. 5C) where the width is less than twice the thickness, and/or any variation in between a rectangular and elliptical cross section. Various other bundle cross-sections may be used. The small surface area and/or the distance from the center of the transformer core may, for example, result in a lower capacitance.

In some embodiments, both primary winding 415 and the secondary winding 310 may be wound around the same section or leg of the transformer core 430. For example, both primary winding 415 and the secondary winding 310 may be wound around the second core leg 432 of the transformer core 430. As another example, both primary winding 415 and the secondary winding 310 may be wound around the first core leg 431 of the transformer core 430. Any number of primary winding and secondary winding may be wound around any of the sections of the transformer core 430. In some embodiments, there may be a large separation between the primary winding and the secondary winding. In some embodiments, the secondary winding are arranged to reduce the stray capacitance between the secondary winding and the primary winding and/or between multiple different secondary winding. Minimizing the surface area of the secondary winding, for example, may help minimize the stray capacitance.

FIG. 5A illustrates a cross-section of a secondary winding 505 according to some embodiments. In this example, the bundle of wires comprising the secondary winding may be arranged to have a circular-cross section or hexagonal-cross section.

FIG. 5B illustrates a cross-section of a secondary winding 510 according to some embodiments. In this example, the bundle of wires comprising the secondary winding may be arranged to have a square-cross section.

FIG. 5C illustrates a cross-section of a secondary winding 515 according to some embodiments. In this example, the bundle of wires comprising the secondary winding may be arranged to have an elliptical-cross section.

FIG. 5D illustrates a cross-section of a secondary winding 520 according to some embodiments. In this example, the bundle of wires comprising the secondary winding may be arranged to have a rectangular-cross section.

In some embodiments, the cross-section of the secondary winding 520 may have a width and a length. In some embodiments, the width to thickness ratio may be less than 3.

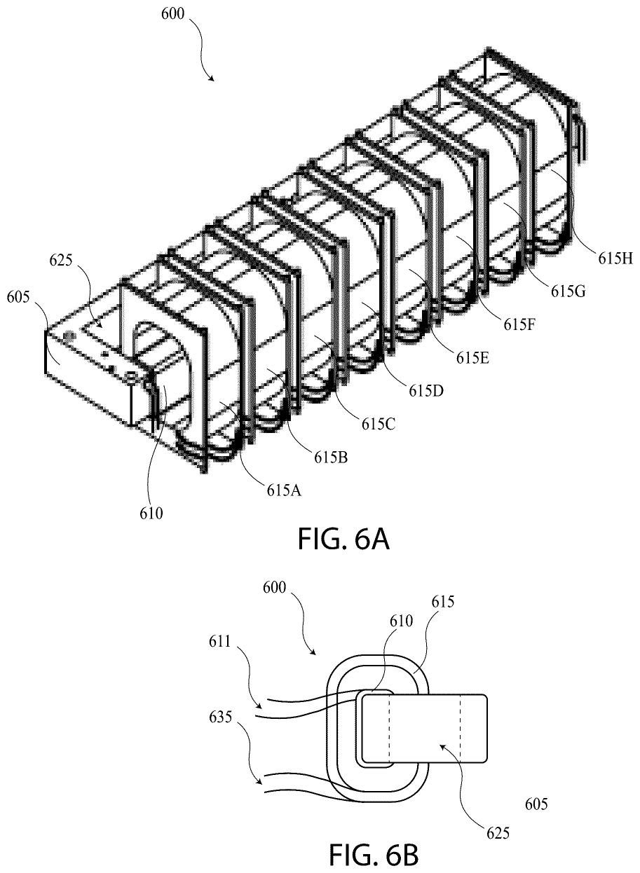

FIG. 6A is an isometric view of an isolation transformer 600 (e.g., isolation transformer 420) according to some embodiments. FIG. 6B illustrates a side view of the isolation transformer 600 according to some embodiments. In some embodiments, isolation transformer 600 may include transformer core 605, primary winding 610 wound about a portion of the transformer core 605, and eight secondary winding 615 wound about portions of the transformer core 605. Any number of secondary windings 615 may be included. In this example, both the primary winding 610 and the secondary winding 615 are wound about the same or substantially the same segment of the transformer core 605. In other embodiments, the primary winding 610 and the secondary winding 615 are wound about the different or substantially different segments of the transformer core 605.

The secondary winding 615 are wound around a portion or leg of the transformer core 605 such that the distance between portions or segments or legs of the transformer core 605 and the secondary winding 615 are maximized. In this example, the secondary winding 615 may pass through the center of the core aperture 625. The primary winding 610 may include electrical leads 611 and each of the secondary winding may include electrical leads 612.

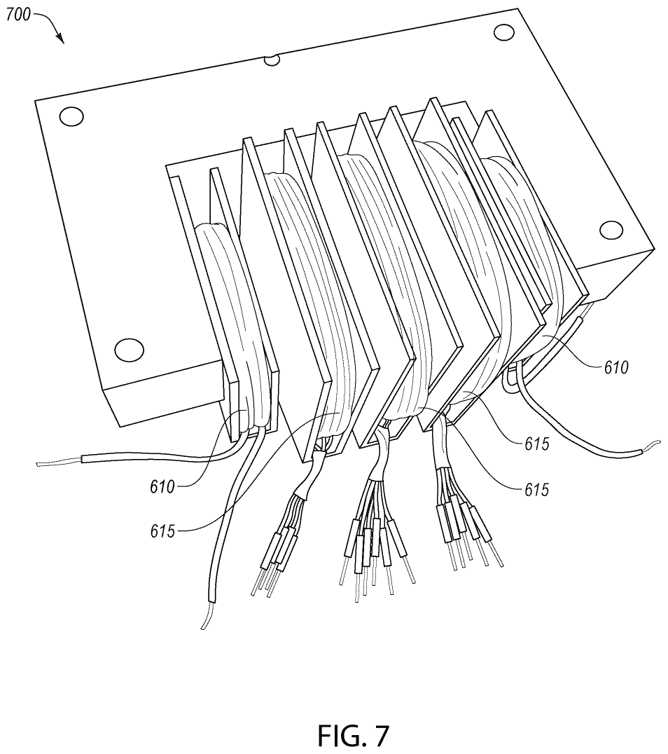

FIG. 7 is an image of an isolation transformer 700 according to some embodiments. In this embodiment, the isolation transformer 700 includes two primary windings 610 and three secondary windings 615. The two primary windings can be wired in series to double the voltage on the primary winding. For example, if the two primary winding are wired in parallel and coupled to 120 VAC source, 120 VAC is applied to the isolation transformer. On the other hand, if the two primary winding are wired in series and 240 VAC source, 240 VAC is applied to the isolation transformer. This transformer, for example, may work with any range of input voltages from 100 VAC to 240 VAC and/or 50 Hz to 60 Hz input frequencies. This may, for example, allows for use with any or all power grids around the world, with the standardly available voltages.

In some embodiments, the ratio of the number of secondary windings to the ratio of the number of primary windings can vary to produce a step-up or a step-down transformer. For example, with 120 VAC applied to the primary winding an output of 19.7 V RMS may be output from each of the secondary winding with a ratio of 6:1 primary winding to secondary winding.

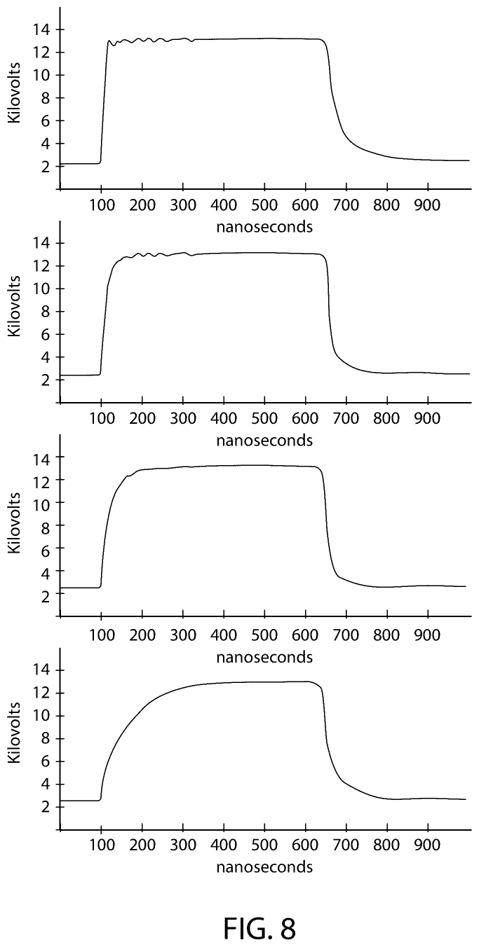

FIG. 8 illustrates four 500 ns waveforms from a high voltage switch that includes sixteen IGBT switch modules driving different loads. The top waveform is from a high voltage switch driving a pulse across a 500 ohm load, the second to the top waveform is from a high voltage switch driving a pulse across a 200 ohm load, the third waveform is from a high voltage switch driving a 1 pulse across a 00 ohm load, and the bottom is from a high voltage switch driving a pulse across a 50 ohm load.

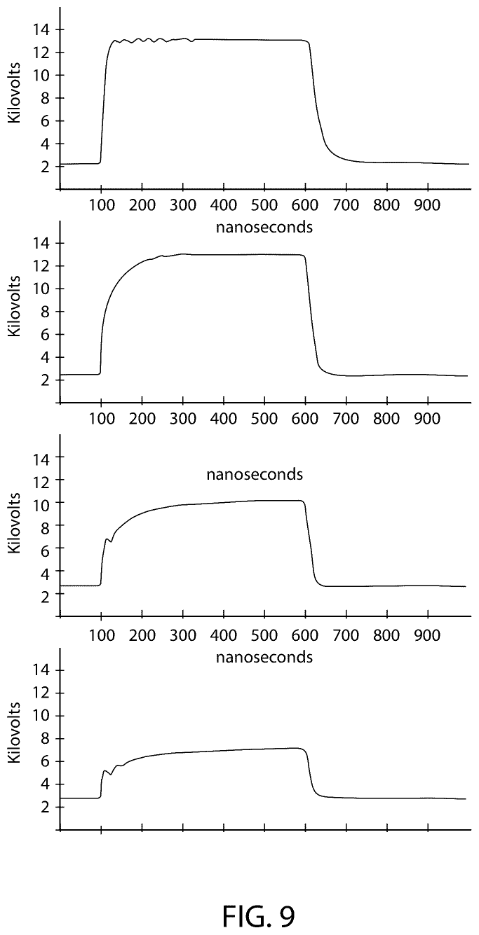

FIG. 9 illustrates four 500 ns waveforms from a high voltage switch that includes sixteen SiC MOSFET switch modules driving different loads. The top waveform is from a high voltage switch driving a pulse across a 500 ohm load, the second to the top waveform is from a high voltage switch driving a pulse across a 200 ohm load, the waveform is from a high voltage switch driving a pulse across a 100 ohm load, and the bottom waveform is from a high voltage switch driving a pulse across a 50 ohm load.

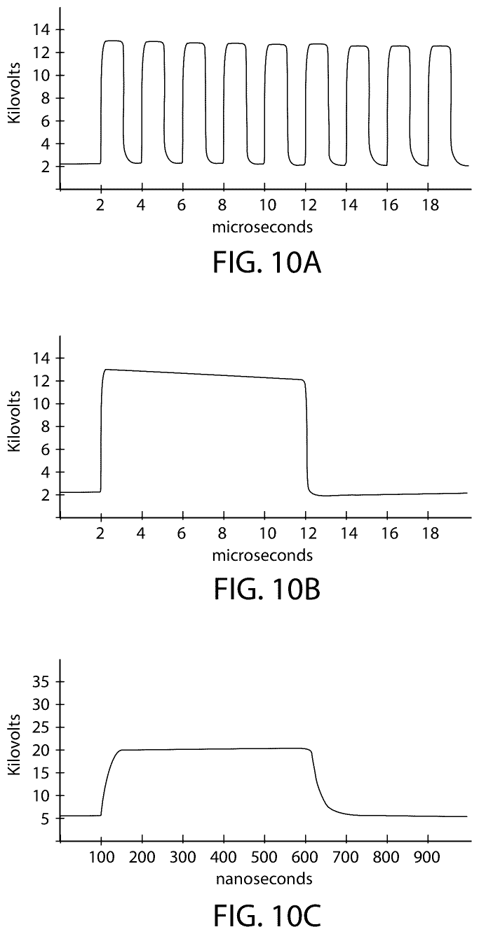

FIG. 10A illustrates a 500 kHz, 12 kV waveform with a 1 μs pulse width from a high voltage switch that includes sixteen IGBT switch modules driving a pulse across a 200 ohm load.

FIG. 10B illustrates a 10 μs, 10 kV burst waveform from a high voltage switch that includes sixteen IGBT switch modules driving a pulse across a 50 ohm load.

FIG. 10C illustrates a 500 ns, 15 kV waveform from a high voltage switch that includes sixteen IGBT switch modules driving a pulse across a 500 ohm load.

In some embodiments of high voltage switches including IGBT switches, the rise time of a pulse may depend on the load and/or the current. In some embodiments of high voltage switches including IGBT switches, the fall time may depend inversely with the current.

In some embodiments, the high voltage switches may include any type of switch such as, for example, solid state switches, IGBT switches, photoconductive switches, GAN switches, silicon switches, silicon carbide switches, etc.

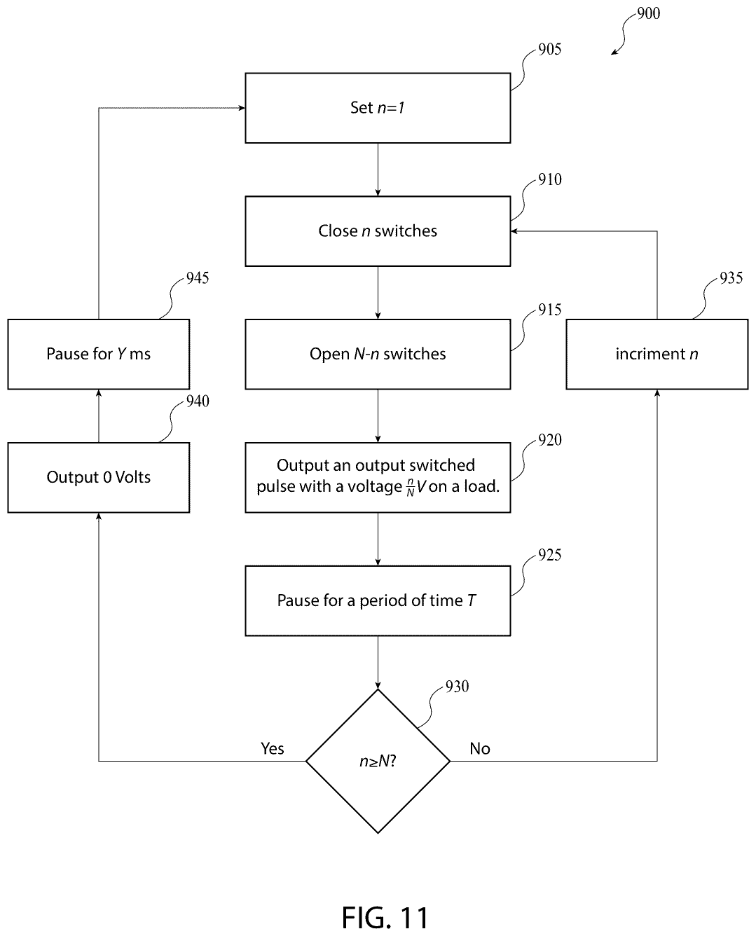

FIG. 11 is flowchart of a process 900 for producing a multilevel waveform using a high voltage switch according to some embodiments. The process 900 includes a number of blocks that may be arranged or rearranged in any order. The process 900 may be used, for example, with the high voltage switch 100.

The process 900 starts at block 905. At block 905, the counter, n, can be set to one.

At block 910, n switches can be closed. At block 915, the remaining N-n switches can be opened, where N equals the number of switches in the high voltage switch. In some embodiments, blocks 910 and 915 can occur simultaneously. If n=1, then a single switch will be closed while the remaining switches, N−1, will be open.

At block 920, a voltage

$$\frac{n}{N} V$$

will be applied to the load, where V is the high voltage provided by such as, for example, the high voltage source 160. For example, if n=1 and N=12, then the voltage applied to the load is one-twelfth the high voltage

$$( \frac{1}{12} V ) .$$

At block 925 the process 900 may pause for a period of time, T. The period of time, T, may, for example, be a time less than about 1 s, 500 ms, 100 ms, 50 ms, 25 ms, 10 ms, 5 ms, etc. The maximum time period, T, may be less than a value determined by the value of the snubber capacitor 120 associated with the switch being closed, the stray capacitance in the switch module 105, and/or the stray inductance in the switch module 105. For example, the maximum time period, T, may be set as the amount of time it takes for the snubber capacitor charge prior to reaching the cutoff voltage of the switch such as, for example, 1 ms to 100 ns.

In some embodiments, the snubber components may be sized to handle such operation where switches are opened and closed with varied timings and sequences. This may result in unusually large amounts of energy in the snubber components in the snubber circuit. In some embodiments, the snubber circuit may include switches and/or resistors that may be used remove stored energy from the snubber circuit.

At block 930 it can be determined if the counter, n, is greater than or equal to the total number of switches, N. If the counter, n, is greater than or equal to the total number of switches, N, then process 900 proceeds to block 940. If the counter, n, is not greater than or equal to the total number of switches, N, then process 900 proceeds to block 935.

At block 935, the counter may be incremented and process 900 proceeds to block 910, such as, for example, setting n=n+1. In some embodiments, the counter may be incremented by any positive or negative integer such as, for example, one, two, three, four, five, etc. In some embodiments, the counter may be incremented a different integer value during each iteration.

At block 940, the output voltage is set to zero volts and at block 945 the process 900 pauses for a second period of time, Y. For example, the second period of time, Y, may be equal to the period of time, T. Alternatively, the second period of time, Y, may be set to any period of time greater or lesser than the period of time, T. The output waveform produced by the process 900 may include the waveform shown in FIG. 12B.

In some embodiments, the process 900 may step down the output pulse voltage. For example, at block 930, it can be determined whether the counter, n, is greater than zero. If the counter, n, is greater than zero, then process 900 can proceed to block 930 where the counter, n, is decremented by an integer (e.g., incremented by a negative integer). If the counter, n, is zero, the process 900 can proceed to block 940. The output waveform produced by the process 900 may include the waveform shown in FIG. 12B.

In some embodiments, a method can produce an upward pulse-step waveform (e.g., as shown in FIG. 12A) followed by producing a downward pulse-step waveform (e.g., as shown in FIG. 12B).

FIG. 12A illustrates an upward pulse-step waveform produced from a high voltage switch according to some embodiments.

FIG. 12B illustrates a downward pulse-step waveform produced from a high voltage switch according to some embodiments.

Unless otherwise specified, the term “substantially” means within 5% or 10% of the value referred to or within manufacturing tolerances. Unless otherwise specified, the term “about” means within 5% or 10% of the value referred to or within manufacturing tolerances.

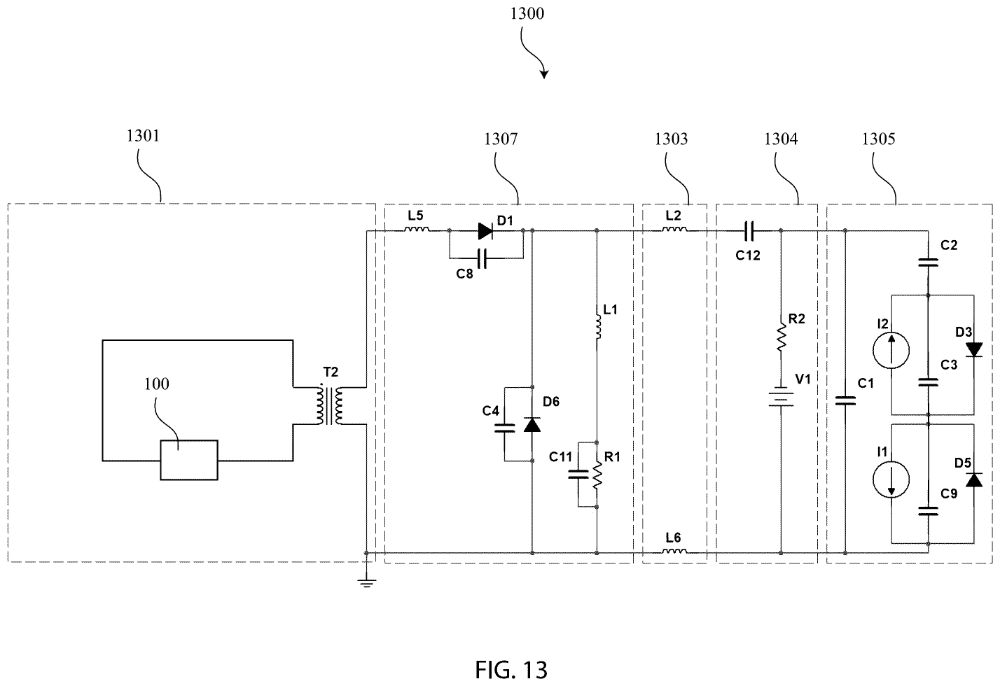

FIG. 13 is a circuit diagram of a high voltage etch system 1300 according to some embodiments. The high voltage etch system 1300 can be generalized into five stages (these stages could be broken down into other stages or generalized into fewer stages and/or may or may not include the components shown in the figure). The high voltage etch system 1300 may include high voltage switch and transformer stage 1301, a resistive output stage 1302, a lead stage 1303, a DC bias power supply stage 1304, and a load stage 1305.

In some embodiments, the high voltage etch system 1300 can produce pulses from the power supply with voltages greater than 5 kV, with rise times less than about 20 ns, and frequencies greater than about 130 kHz.

In some embodiments, the high voltage switch and transformer stage 1301 can produce a plurality of high voltage pulses with a high frequency and fast rise times and fall times.

In some embodiments, the high voltage switch and transformer stage 1301 can include one or more high voltage switches 100, which may include any high voltage switch disclosed or described in this document.

In some embodiments, the load stage 1305 may represent an effective circuit for a plasma deposition system, plasma etch system, or plasma sputtering system. In some embodiments, the plasma etch system may include effective components that represent the physics of the plasma and or a wafer. The capacitance C2 may represent the capacitance of the dielectric material upon which a wafer may sit. The capacitor C3 may represent the sheath capacitance of the plasma to the wafer. The capacitor C9 may represent capacitance within the plasma between a chamber wall and the top surface of the wafer. The current source 12 and the current source I1 may represent the ion current through the sheath.

In some embodiments, the load stage 1305 may represent a plasma type load. In some embodiments, the plasma load may have a capacitance less than about 100 nF, 50 nF, 20 nF, 10 nF, etc.

In some embodiments, the resistive output stage 1302 may include one or more inductive elements represented by inductor L1 and/or inductor L5. The inductor L5, for example, may represent the stray inductance of the leads in the resistive output stage 1302. Inductor L1 may be set to minimize the power that flows directly from the high voltage switch and transformer stage 1301 into resistor R1.

In some embodiments, the resistor R1 may dissipate charge from the load stage 1305, for example, on fast time scales (e.g., 1 ns, 130 ns, 50 ns, 1300 ns, 250 ns, 500 ns, 1,000 ns, etc. time scales). The resistance of resistor R1 may be low to ensure the pulse across the load stage 1305 has a fast fall time t_{f}.

In some embodiments, the resistor R1 may include a plurality of resistors arranged in series and/or parallel. The capacitor C11 may represent the stray capacitance of the resistor R1 including the capacitance of the arrangement series and/or parallel resistors. The capacitance of stray capacitance C11, for example, may be less than 500 pF, 250 pF, 1300 pF, 50 pF, 130 pF, 1 pF, etc. The capacitance of stray capacitance C11, for example, may be less than the load capacitance such as, for example, less than the capacitance of C2, C3, and/or C9.

In some embodiments, a plurality of high voltage and transformer stages 1301 can be ganged up in parallel and coupled with the resistive output stage 1302 across the inductor L1 and/or the resistor R1. Each of the plurality of high voltage switch and transformer stages 1301 may each also include diode D1 and/or diode D6.

In some embodiments, the capacitor C8 may represent the stray capacitance of the blocking diode D1. In some embodiments, the capacitor C4 may represent the stray capacitance of the diode D6.

In some embodiments, the DC bias power supply stage 1304 may include DC a voltage source V1 that can be used to bias the output voltage either positively or negatively. In some embodiments, the capacitor C12 isolates/separates the DC bias voltage from the resistive output stage and other circuit elements. It allows for a potential shift from one portion of the circuit to another. In some applications the potential shift it establishes is used to hold a wafer in place. Resistance R2 may protect/isolate the DC bias supply from the high voltage pulsed output from the high voltage switch and transformer stage 1301.

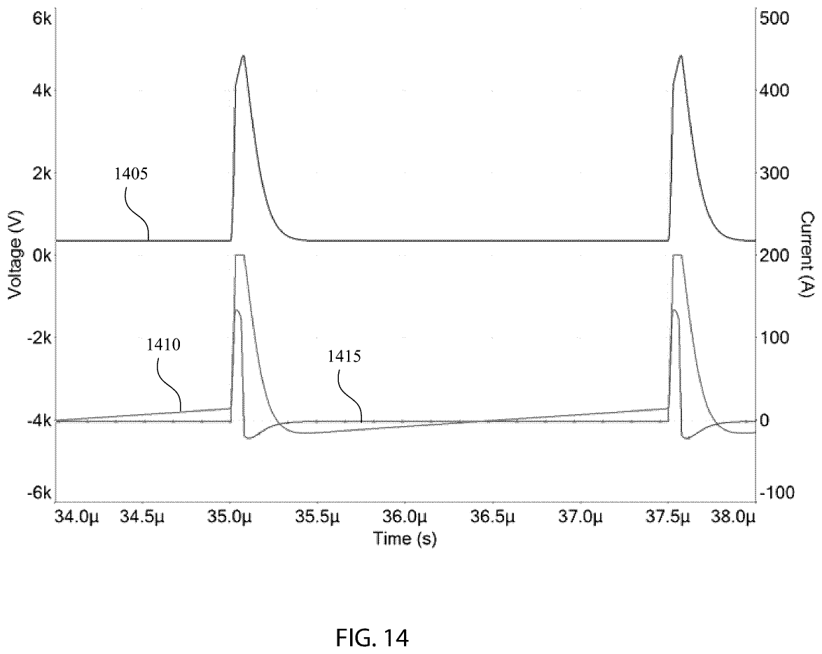

FIG. 14 shows example waveforms produced by the high voltage etch system 1300. In these example waveforms, the pulse waveform 1405 may represent the voltage provided by the high voltage switch and transformer stage 1301. As shown, the pulse waveform 1405 produces a pulse with the following qualities: high voltage (e.g., greater than about 4 kV as shown in the waveform), a fast rise time (e.g., less than about 200 ns as shown in the waveform), a fast fall time (e.g., less than about 200 ns as shown in the waveform), and short pulse width (e.g., less than about 300 ns as shown in the waveform). The waveform 1410 may represent the voltage at the surface of a wafer represented in circuit 1300 by the point between capacitor C2 and capacitor C3 or the voltage across capacitor C3. The pulse waveform 1415 represent the current flowing from the switch and transformer stage 1301 to the plasma. The circuit 1300 may or may not include either or both diodes D1 or D2.

During the transient state (e.g., during an initial number of pulses not shown in the figure), the high voltage pulses from the switch and transformer stage 1301 charge the capacitor C2. Because the capacitance of capacitor C2 is large compared to the capacitance of capacitor C3 and/or capacitor C1, and and/or because of the short pulse widths of the pulses, the capacitor C2 may take a number of pulses from the high voltage switch to fully charge. Once the capacitor C2 is charged the circuit reaches a steady state, as shown by the waveforms in FIG. 14.

In steady state and when the switch S1 is open, the capacitor C2 is charged and slowly dissipates through the resistive output stage 1310, as shown by the slightly rising slope of waveform 1410. Once the capacitor C2 is charged and while the switch S1 is open, the voltage at the surface of the waver (the point between capacitor C2 and capacitor C3) is negative. This negative voltage may be the negative value of the voltage of the pulses provided by the high voltage switch and transformer stage 1301. For the example waveform shown in FIG. 14, the voltage of each pulse is about 4 kV; and the steady state voltage at the wafer is about −4 kV. This results in a negative potential across the plasma (e.g., across capacitor C3) that accelerates positive ions from the plasma to the surface of the wafer. While the switch S1 is open, the charge on capacitor C2 slowly dissipates through the resistive output stage.

When the switch S1 is closed, the voltage across the capacitor C2 may flip (the pulse from the high voltage switch 100 is high as shown in waveform 1405) as the capacitor C2 is charged. In addition, the voltage at the point between capacitor C2 and capacitor C3 (e.g., at the surface of the wafer) changes to about zero as the capacitor C2 charges, as shown in waveform 1410. Thus, the pulses from the high voltage switch 100 produce a plasma potential (e.g., a potential in a plasma) that rise from a negative high voltage to zero and returns to the negative high voltage at high frequencies, with fast rise times, fast fall times, and/or short pulse widths.

In some embodiments, the action of the resistive output stage, elements represented by the resistive output stage 1302, that may rapidly discharge the stray capacitance C1, and may allow the voltage at the point between capacitor C2 and capacitor C3 to rapidly return to its steady negative value of about −4 kV as shown by waveform 1410. The resistive output stage may allow the voltage at the point between capacitor C2 and capacitor C3 to exists for about % of the time, and thus maximizes the time which ions are accelerated into the wafer. In some embodiments, the components contained within the resistive output stage may be specifically selected to optimize the time during which the ions are accelerated into the wafer, and to hold the voltage during this time approximately constant. Thus, for example, a short pulse with fast rise time and a fast fall time may be useful, so there can be a long period of fairly uniform negative potential.

Various other waveforms may be produced by the high voltage etch system 1300.

In some embodiments, a bias compensation subsystem can be used to adjust the chucking voltage in a semiconductor fabrication wafer chamber. A chucking voltage can be applied to the chuck to track the on/off pattern of the pulse bias generator bursts, for example, so that there is a constant voltage difference.

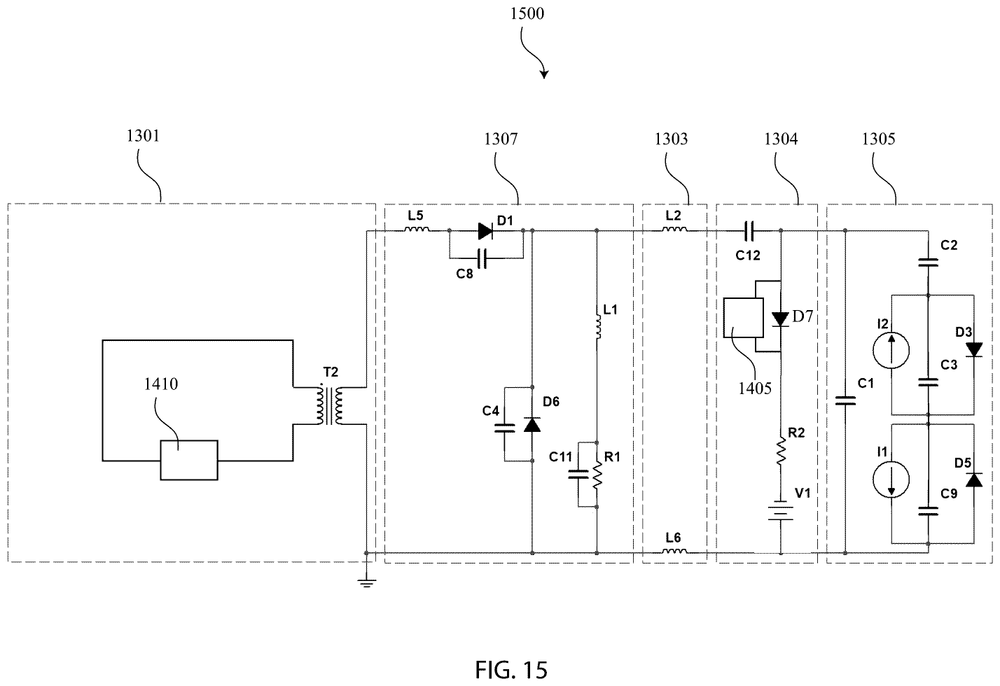

FIG. 15 is a circuit diagram of a high voltage etch system 1500 according to some embodiments. In some embodiments, the high voltage etch system 1500 may include a high voltage switch 1405 coupled across a blocking diode D7 at, near or within the resistive output stage 1302 and or the DC bias power supply stage 1304.

In some embodiments, the high voltage switch 1405 may be open while the switch 1410 is pulsing and closed when the switch 1410 is not pulsing. While closed, the high voltage switch 1405 may, for example, short current across diode D7. Shorting this current may allow the bias between the wafer and the chuck to be less than 2 kV, which may be within acceptable tolerances. The switch 1410 may be any power supply such as, for example, a high voltage switch 100, a nanosecond pulser, an RF power supply, etc.

Systems and methods are disclosed to produce different high voltage pulses on different electrodes. For example, each of a plurality of pulse generators (e.g., nanosecond pulsers, RF generators, or HV switches) can be electrically coupled with a respective one of a plurality of electrodes. The plurality of pulse generators can produce a different voltage, ion energy, or electric field on the electrodes. This can be done for any number of reasons such, for example, to compensate for plasma chamber defects, wafer discontinuities, or reduce wafer edge defects. In one example, the plurality of pulse generators systems may be used to produce a different electric field profile at the edge of a wafer than in the middle of the wafer.

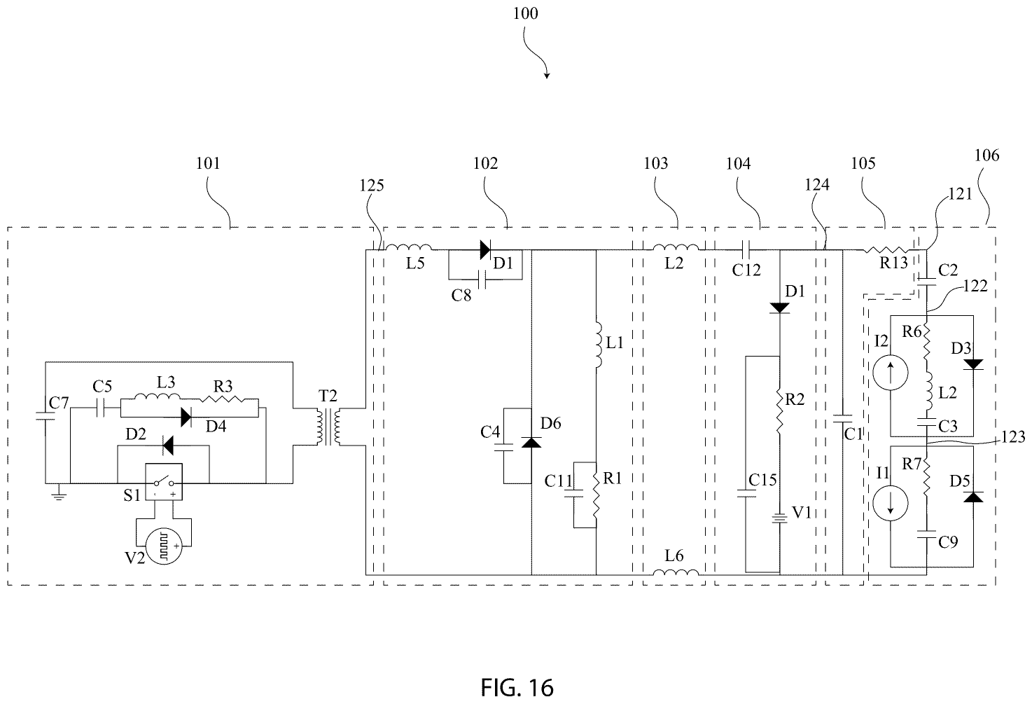

Reference numerals in FIGS. 16-24 do not necessarily correspond with reference numerals in FIGS. 1-15.

FIG. 16 is a circuit diagram of a nanosecond pulser system 100 according to some embodiments. The nanosecond pulser system 100 can be implemented within a high voltage nanosecond pulser system. The nanosecond pulser system 100 can be generalized into five stages (these stages could be broken down into other stages or generalized into fewer stages and/or may or may not include the components shown in the figure). The nanosecond pulser system 100 includes a pulser and transformer stage 101, a resistive output stage 102, a lead stage 103, a DC bias compensation circuit 104, and a load stage 106.

In some embodiments, the nanosecond pulser system 100 can produce pulses from the power supply with voltages greater than 2 kV, with rise times less than about 20 ns, and frequencies greater than about 10 KHz.

In some embodiments, the pulser and transformer stage 101 can produce a plurality of high voltage pulses with a high frequency and fast rise times and fall times. In all of the circuits shown, the high voltage pulser may comprise a nanosecond pulser.

In some embodiments, the pulser and transformer stage 101 can include one or more solid state switches S1 (e.g., solid state switches such as, for example, IGBTs, a MOSFETs, a SiC MOSFETs, SiC junction transistors, FETs, SiC switches, GaN switches, photoconductive switches, etc.), one or more snubber resistors R3, one or more snubber diodes D4, one or more snubber capacitors C5, and/or one or more freewheeling diodes D2. One or more switches and or circuits can be arranged in parallel or series.

In some embodiments, the load stage 106 may represent an effective circuit for a plasma deposition system, plasma etch system, or plasma sputtering system. The capacitance C2 may represent the capacitance of the dielectric material upon which a wafer may sit or capacitance C2 may represent the capacitance between an electrode and a wafer which are separated by a dielectric material. The capacitor C3 may represent the sheath capacitance of the plasma to the wafer. The capacitor C9 may represent capacitance within the plasma between a chamber wall and the top surface of the wafer. The current source 12 and the current source I1 may represent the ion current through the plasma sheaths.

In some embodiments, the resistive output stage 102 may include one or more inductive elements represented by inductor L1 and/or inductor L5. The inductor L5, for example, may represent the stray inductance of the leads in the resistive output stage 102. Inductor L1 may be set to minimize the power that flows directly from the pulser and transformer stage 101 into resistor R1.

In some embodiments, the resistor R1 may dissipate charge from the load stage 106, for example, on fast time scales (e.g., 1 ns, 10 ns, 50 ns, 100 ns, 250 ns, 500 ns, 1,000 ns, etc. time scales). The resistance of resistor R1 may be low to ensure the pulse across the load stage 106 has a fast fall time t_{f}.

In some embodiments, the resistor R1 may include a plurality of resistors arranged in series and/or parallel. The capacitor C11 may represent the stray capacitance of the resistor R1 including the capacitance of the arrangement series and/or parallel resistors. The capacitance of stray capacitance C11, for example, may be less than 5 nF, 2 nF, 1 nF, 500 pF, 250 pF, 100 pF, 50 pF, 10 pF, 1 pF, etc. The capacitance of stray capacitance C11, for example, may be less than the load capacitance such as, for example, less than the capacitance of C2, C3, and/or C9.

In some embodiments, a plurality of pulser and transformer stages 101 can be arranged in parallel and coupled with the resistive output stage 102 across the inductor L1 and/or the resistor R1. Each of the plurality of pulser and transformer stages 101 may each also include diode D1 and/or diode D6.

In some embodiments, the capacitor C8 may represent the stray capacitance of the blocking diode D1. In some embodiments, the capacitor C4 may represent the stray capacitance of the diode D6.

In some embodiments, the DC bias compensation circuit 104 may include a DC voltage source V1 that can be used to bias the output voltage either positively or negatively. In some embodiments, the capacitor C12 isolates/separates the DC bias voltage from the resistive output stage and other circuit elements. It allows for a potential shift from one portion of the circuit to another. In some applications the potential shift it establishes is used to hold a wafer in place. Resistance R2 may protect/isolate the DC bias supply from the high voltage pulsed output from the pulser and transformer stage 101.

In this example, the DC bias compensation circuit 104 is a passive bias compensation circuit and can include a bias compensation diode D1 and a bias compensation capacitor C15. The bias compensation diode C15 can be arranged in series with offset supply voltage V1. The bias compensation capacitor C15 can be arranged across either or both the offset supply voltage V1 and the resistor R2. The bias compensation capacitor C15 can have a capacitance less than 100 nH to 100 μF such as, for example, about 100 μF, 50 μF, 25 μF, 10 μF, 2μ, 500 nH, 200 nH, etc.

In some embodiments, the bias capacitor C12 may allow for a voltage offset between the output of the pulser and transformer stage 101 (e.g., at the position labeled 125) and the voltage on the electrode (e.g., at the position labeled 124). In operation, the electrode may, for example, be at a DC voltage of −2 kV during a burst, while the output of the nanosecond pulser alternates between +6 kV during pulses and 0 kV between pulses.

The bias capacitor C12, for example, 100 nF, 10 nF, 1 nF, 100 μF, 10 μF, 1 μF, etc. The resistor R2, for example, may have a high resistance such as, for example, a resistance of about 1 kOhm, 10 kOhm, 100 kOhm, 1 MOhm, 10 MOhm, 100 MOhm, etc.

In some embodiments, the bias compensation capacitor C15 and the bias compensation diode D1 may allow for the voltage offset between the output of the pulser and transformer stage 101 (e.g., at the position labeled 125) and the voltage on the electrode (e.g., at the position labeled 124) to be established at the beginning of each burst, reaching the needed equilibrium state. For example, charge is transferred from bias capacitor C12 into bias compensation capacitor C15 at the beginning of each burst, over the course of a plurality of pulses (e.g., about 5-100 pulses), establishing the correct voltages in the circuit.

In some embodiments, the DC bias compensation circuit 104 may include one or more high voltage switches placed across the bias compensation diode D1 and coupled with the power supply V1. In some embodiments, a high voltage switch may include a plurality of switches arranged in series to collectively open and close high voltages.

A high voltage switch may be coupled in series with either or both an inductor and a resistor. The inductor may limit peak current through high voltage switch. The inductor, for example, may have an inductance less than about 100 pH such as, for example, about 250 μH, 100 μH, 50 μH, 25 μH, 10 μH, 5 μH, 1 μH, etc. The resistor, for example, may shift power dissipation to the resistive output stage 102. The resistance of resistor may have a resistance of less than about 1,000 ohms, 500 ohms, 250 ohms, 100 ohms, 50 ohms, 10 ohms, etc.

In some embodiments, a high voltage switch may include a snubber circuit.

In some embodiments, the high voltage switch may include a plurality of switches arranged in series to collectively open and close high voltages. For example, the high voltage switch may, for example, include any switch described in U.S. patent application Ser. No. 16/178,565, filed Nov. 1, 2018, titled “High Voltage Switch with Isolated Power,” which is incorporated into this disclosure in its entirety for all purposes.

In some embodiments, a high voltage switch may be open while the pulser and transformer stage 101 is pulsing and closed when the pulser and transformer stage 101 is not pulsing. When the high voltage switch is closed, for example, current can short across the bias compensation diode C15. Shorting this current may allow the bias between the wafer and the chuck to be less than 2 kV, which may be within acceptable tolerances.

In some embodiments, the pulser and transformer stage 101 can produce pulses having a high pulse voltage (e.g., voltages greater than 1 kV, 10 kV, 20 kV, 50 kV, 100 kV, etc.), high pulse repetition frequencies (e.g., frequencies greater than 1 kHz, 10 kHz, 100 kHz, 200 kHz, 500 kHz, 1 MHz, etc.), fast rise times (e.g., rise times less than about 1 ns, 10 ns, 50 ns, 100 ns, 250 ns, 500 ns, 1,000 ns, etc.), fast fall times (e.g., fall times less than about 1 ns, 10 ns, 50 ns, 100 ns, 250 ns, 500 ns, 1,000 ns, etc.) and/or short pulse widths (e.g., pulse widths less than about 1,000 ns, 500 ns, 250 ns, 100 ns, 20 ns, etc.).

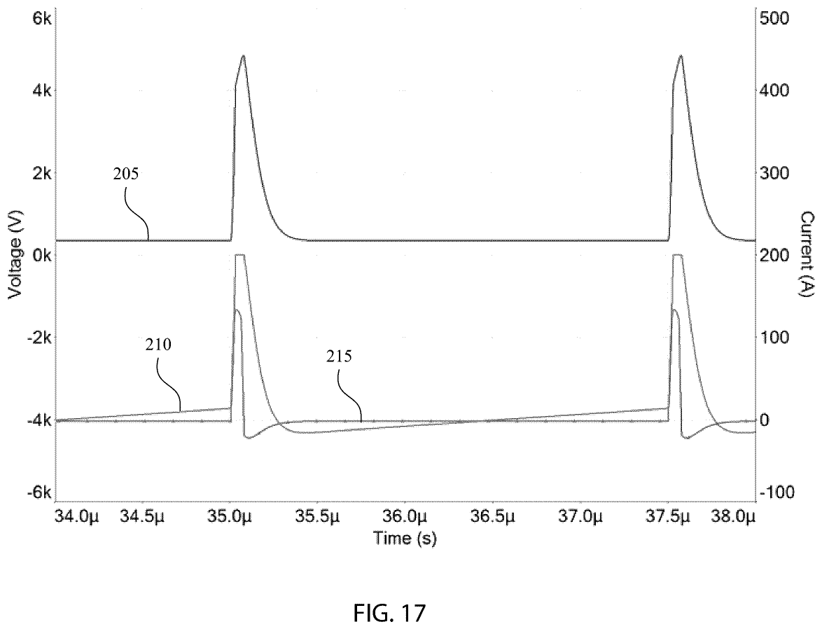

FIG. 17 shows example waveforms produced by the nanosecond pulser system 100. In these example waveforms, the pulse waveform 205 may represent the voltage provided by the pulser and transformer stage 101. As shown, the pulse waveform 205 produces a pulse with the following qualities: high voltage (e.g., greater than about 4 kV as shown in the waveform), a fast rise time (e.g., less than about 200 ns as shown in the waveform), a fast fall time (e.g., less than about 200 ns as shown in the waveform), and short pulse width (e.g., less than about 300 ns as shown in the waveform). The waveform 210 may represent the voltage at the surface of a wafer represented in the circuit shown in FIG. 16 by the point between capacitor C2 and capacitor C3 or the voltage across capacitor C3. The pulse waveform 215 represent the current flowing from the pulser and transformer stage 101 to the plasma. The nanosecond pulser system 100 may or may not include either or both diodes D1 or D2.

During the transient state (e.g., during an initial number of pulses not shown in the figure), the high voltage pulses from the pulser and transformer stage 101 charge the capacitor C2. Because the capacitance of capacitor C2 is large compared to the capacitance of capacitor C3 and/or capacitor C1, and and/or because of the short pulse widths of the pulses, the capacitor C2 may take a number of pulses from the high voltage pulser to fully charge. Once the capacitor C2 is charged the circuit reaches a steady state, as shown by the waveforms in FIG. 2.

In steady state and when the switch S1 is open, the capacitor C2 is charged and slowly dissipates through the resistive output stage 102, as shown by the slightly rising slope of waveform 210. Once the capacitor C2 is charged and while the switch S1 is open, the voltage at the surface of the waver (the point between capacitor C2 and capacitor C3) is negative. This negative voltage may be the negative value of the voltage of the pulses provided by the pulser and transformer stage 101. For the example waveform shown in FIG. 17, the voltage of each pulse is about 4 kV; and the steady state voltage at the wafer is about −4 kV. This results in a negative potential across the plasma (e.g., across capacitor C3) that accelerates positive ions from the plasma to the surface of the wafer. While the switch S1 is open, the charge on capacitor C2 slowly dissipates through the resistive output stage.

When the switch S1 is closed, the voltage across the capacitor C2 may flip (the pulse from the pulser is high as shown in the pulse waveform 205) as the capacitor C2 is charged. In addition, the voltage at the point between capacitor C2 and capacitor C3 (e.g., at the surface of the wafer) changes to about zero as the capacitor C2 charges, as shown in waveform 210. Thus, the pulses from the high voltage pulser produce a plasma potential (e.g., a potential in a plasma) that rise from a negative high voltage to zero and returns to the negative high voltage at high frequencies, with fast rise times, fast fall times, and/or short pulse widths.

In some embodiments, the action of the resistive output stage, elements represented by the resistive output stage 102, that may rapidly discharge the stray capacitance C1, and may allow the voltage at the point between capacitor C2 and capacitor C3 to rapidly return to its steady negative value of about −4 kV as shown by waveform 210. The resistive output stage may allow the voltage at the point between capacitor C2 and capacitor C3 to exists for about % of the time, and thus maximizes the time which ions are accelerated into the wafer. In some embodiments, the components contained within the resistive output stage may be specifically selected to optimize the time during which the ions are accelerated into the wafer, and to hold the voltage during this time approximately constant. Thus, for example, a short pulse with fast rise time and a fast fall time may be useful, so there can be a long period of fairly uniform negative potential.

Various other waveforms may be produced by the nanosecond pulser system 100.

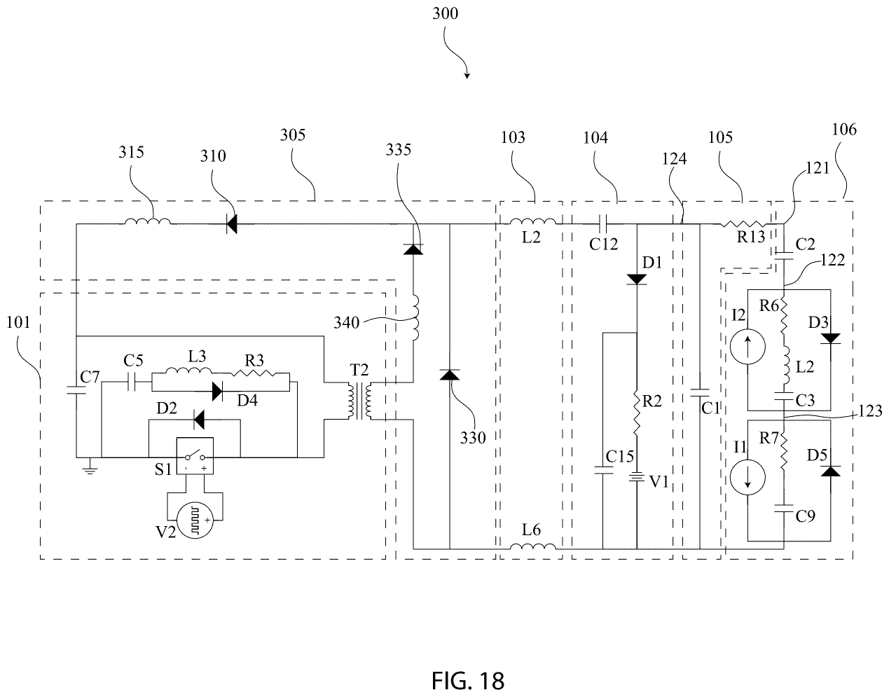

FIG. 18 is a circuit diagram of a nanosecond pulser system 300 with the pulser and transformer stage 101 and an energy recovery circuit 305 according to some embodiments. The energy recovery circuit, for example, may replace the resistive output stage 102 shown in FIG. 1. In this example, the energy recovery circuit 305 may be positioned on or electrically coupled with the secondary side of the transformer T1. The energy recovery circuit 305, for example, may include a diode 330 (e.g., a crowbar diode) across the secondary side of the transformer T1. The energy recovery circuit 305, for example, may include diode 310 and inductor 315 (arranged in series), which can allow current to flow from the secondary side of the transformer T1 to charge the power supply C7. The diode 310 and the inductor 315 may be electrically connected with the secondary side of the transformer T1 and the power supply C7. In some embodiments, the energy recovery circuit 305 may include diode 335 and/or inductor 340 electrically coupled with the secondary of the transformer T1. The inductor 340 may represent the stray inductance and/or may include the stray inductance of the transformer T1.

When the nanosecond pulser is turned on, current may charge the load stage 106 (e.g., charge the capacitor C3, capacitor C2, or capacitor C9). Some current, for example, may flow through inductor 315 when the voltage on the secondary side of the transformer T1 rises above the charge voltage on the power supply C7. When the nanosecond pulser is turned off, current may flow from the capacitors within the load stage 106 through the inductor 315 to charge the power supply C7 until the voltage across the inductor 315 is zero. The diode 330 may prevent the capacitors within the load stage 106 from ringing with the inductance in the load stage 106 or the DC bias compensation circuit 104.

The diode 310 may, for example, prevent charge from flowing from the power supply C7 to the capacitors within the load stage 106.

The value of inductor 315 can be selected to control the current fall time. In some embodiments, the inductor 315 can have an inductance value between 1 μH-500 μH.

In some embodiments, the energy recovery circuit 305 may include an energy recovery switch that can be used to control the flow of current through the inductor 315. The energy recovery switch, for example, may be placed in series with the inductor 315. In some embodiments, the energy recovery switch may be closed when the switch S1 is open and/or no longer pulsing to allow current to flow from the load stage 106 back to the high voltage load C7.

In some embodiments, the energy recovery switch may include a plurality of switches arranged in series to collectively open and close high voltages. For example, the energy recovery switch may, for example, include any switch described in U.S. patent application Ser. No. 16/178,565, filed Nov. 1, 2018, titled “High Voltage Switch with Isolated Power,” which is incorporated into this disclosure in its entirety for all purposes.

In some embodiments, the nanosecond pulser system 300 may produce similar waveforms as those shown in FIG. 17.

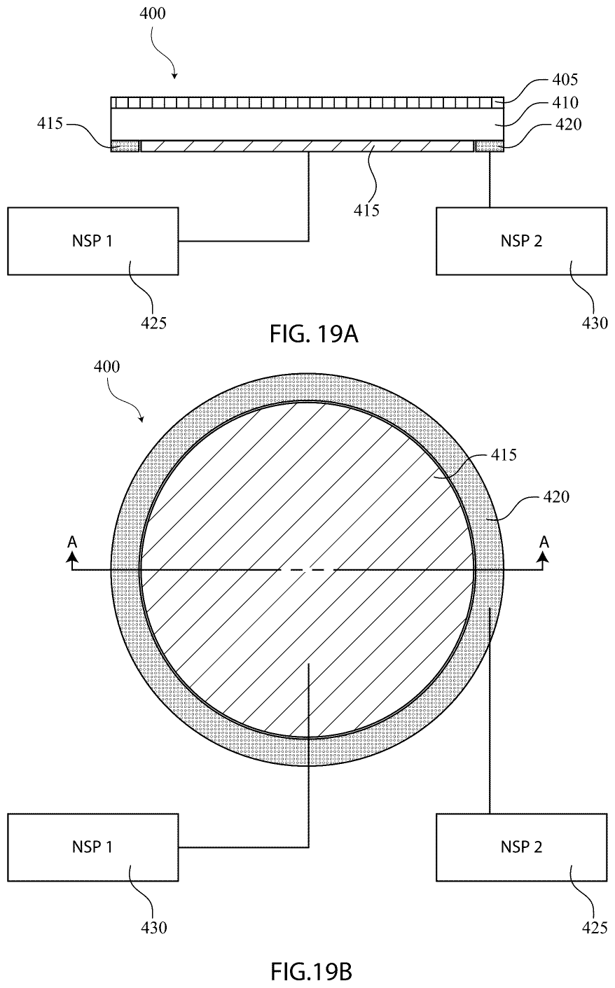

FIG. 19A is a cutaway side view block diagram and FIG. 19B is a top view block diagram of a spatially variable wafer bias power system 400 according to some embodiments. The cutaway side view shown in FIG. 19A is along the line A shown in FIG. B. The spatially variable wafer bias power system 400 includes two electrodes: a first electrode 415 and a second electrode 420. A wafer 405 may be placed on a wafer platform 410 above both the first electrode 415 and the second electrode 420. The wafer platform 410 may comprise a dielectric material such as, for example, a ceramic. The first electrode 415 may be disc shaped with a diameter that is smaller than the diameter of either or both the wafer platform 410 or the wafer 405. The second electrode 420 may have a donut shape with an aperture diameter that is slightly greater than the diameter of the first electrode 415 and an exterior diameter that is substantially similar to either or both the diameter of the wafer platform 410 or the wafer 405. The first electrode 415 may be placed within the aperture of the second electrode 420.

In some embodiments, the gap between the first electrode 415 and the second electrode 420 may be less than about 0.1 mm, 1.0 mm, 5.0 mm, etc. In some embodiments, the space between the first electrode 415 and the second electrode 420 may be filled with air, vacuum, insulating gas, solid dielectric material, or other insulating material.

In some embodiments, the thickness of the first electrode 415 and the second electrode 420 may be substantially the same thickness. In some embodiments, the first electrode 415 and the second electrode 420 may have different thickness.

In some embodiments, the second electrode 420 may have an area that is 5% to 50% of the area of the wafer platform.

In some embodiments, the first electrode 415 and the second electrode 420 may comprise the same material or different material.

In some embodiments, a first high voltage pulser 425 may be coupled with the first electrode 415 and a second high voltage pulser 430 may be coupled with the second electrode 420. For example, the first high voltage pulser 425 and the second high voltage pulser 430 may include the pulser and transformer stage 101 of nanosecond pulser system 100.

In some embodiments, the first high voltage pulser 425 and the second high voltage pulser 430 may provide different pulses. For example, the peak voltage provided by the second high voltage pulser 430 to the second electrode 420 may be different than the peak voltage provided by the first high voltage pulser 425 to the first electrode 415. As another example, the pulse repetition frequency provided by the second high voltage pulser 430 to the second electrode 420 may be different than the pulse repetition frequency provided by the first high voltage pulser 425 to the first electrode 415. As another example, the ion current provided by the second high voltage pulser 430 to the second electrode 420 may be different than the ion current provided by the first high voltage pulser 425 to the first electrode 415.

In some embodiments, the first high voltage pulser 425 and the second high voltage pulser may provide substantially the same pulses. For example, the peak voltage provided by the second high voltage pulser 430 to the second electrode 420 may be substantially the same as the peak voltage provided by the first high voltage pulser 425 to the first electrode 415. As another example, the pulse repetition frequency provided by the second high voltage pulser 430 to the second electrode 420 may be substantially the same as the pulse repetition frequency provided by the first high voltage pulser 425 to the first electrode 415. As another example, the ion current provided by the second high voltage pulser 430 to the second electrode 420 may be substantially the same as the ion current provided by the first high voltage pulser 425 to the first electrode 415.

The first high voltage pulser 425 may include any or all components of the nanosecond pulser system 100. The first high voltage pulser 425 may include any or all components of the nanosecond pulser system 300. In some embodiments, the first high voltage pulser 425 may include any switch described in U.S. patent application Ser. No. 16/178,565, filed Nov. 1, 2018, titled “High Voltage Switch with Isolated Power,” which is incorporated into this disclosure in its entirety for all purposes. In some embodiments, the first high voltage pulser 425 may include an RF generator.

The second high voltage pulser 430 may include any or all components of the nanosecond pulser system 100. The second high voltage pulser 430 may include any or all components of the nanosecond pulser system 300. In some embodiments, the second high voltage pulser 430 may include any switch described in U.S. patent application Ser. No. 16/178,565, filed Nov. 1, 2018, titled “High Voltage Switch with Isolated Power,” which is incorporated into this disclosure in its entirety for all purposes. In some embodiments, second high voltage pulser 430 may include an RF generator.

In some embodiments, the first high voltage pulser 425 and the second high voltage pulser 430 may provide separately controlled pulse bias voltages or distinct pulse repetition frequencies or pulses that are out of phase such that the voltage pulses applied to the edge of the wafer by the second electrode 420 is distinct from the voltage applied to the center of the wafer by the first electrode 415. Separate voltages may, for example, produce different electric field profiles at the wafer edge compared to center such that the electric field or bias voltage across the wafer 405 is uniform. This may, for example, optimize wafer yield. In some embodiments, the second high voltage pulser 430 may operate at a lower voltage than the first high voltage pulser 425 such as, for example, the second high voltage pulser 430 may operate at 5%, 10%, 15%, 20%, 25%, 30%, etc. of the voltage of the first high voltage pulser 425.

In some embodiments, the pulses provided by the first high voltage pulser 425 may be independently controlled relative to the second high voltage pulser 430.

In some embodiments, the spatially variable wafer bias power system may produce a uniform electric field (e.g., differences less than about 5%, 10%, 15%, or 20%) or uniform voltage across the top of the wafer platform 410 or the wafer 405.

In some embodiments, the spatially variable wafer bias power system may produce a nonuniform electric field or nonuniform voltage across the top of the wafer platform 410 or the wafer 405.

In some embodiments, the first high voltage pulser 425 and the second high voltage pulser 430 may be capacitively coupled with a capacitance between about 1 pF and 100 nF.

In some embodiments, the first high voltage pulser 425 and the second high voltage pulser 430 may be linked. For example, the first high voltage pulser 425 and the second high voltage pulser 430 may comprise a single nanosecond pulser with a voltage divider (e.g., resistive, inductive, or capacitive) that produces different voltages for the first electrode 415 and the second electrode 420. As another example, a single pulser on the primary side of the transformer may be coupled with multiple loads (and energy recovery circuits, resistive output stages, or bias compensation circuits) coupled with different secondary windings on the secondary side of the transformer T2. The different secondary windings may have a different number of windings to produce different voltages.

While two electrodes are shown in FIG. 19A, in some embodiments, any number of electrodes may be used along with any number of nanosecond pulsers. In some embodiments, the first electrode 415 or the second electrode 420 may comprise any geometric region beneath the wafer platform 410 having any geometric shape. Similarly, additional electrodes and nanosecond pulsers may be included and the additional electrodes may have any shape and disposed in any location relative to the other electrodes and relative to the wafer platform.

In some embodiments, the leads from the first high voltage pulser 425 to the first electrode 415 and the leads from the second high voltage pulser 430 to the second electrode 420 may be grouped or bundled together. This bundling, for example, may allow the total stray capacitance to ground of the bundled leads to be less than if each lead was run separately. This bundling, for example, may also conserve power consumption. In some embodiments, the leads may be arranged in a coaxial configuration or in twin lead configuration or as a twisted pair. In some embodiments, the stray capacitance from the outputs to ground may be less than about 100 pF or less than about 1 nF or 10 nF, etc. In some embodiments, the stray inductance of the outputs may be less than about 100 nH, 1 μH, 10 μH, etc. In some embodiments, the capacitive coupling between each output may be less than about 100 pF, 1 nF, 10 nF, etc.

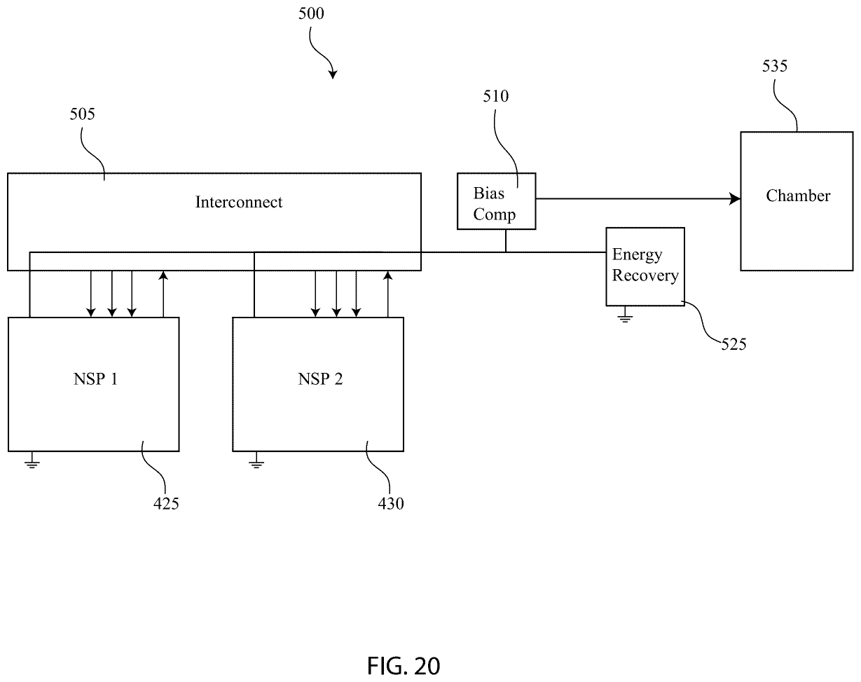

FIG. 20 is a block diagram of a spatially variable wafer bias power system 500 according to some embodiments. The spatially variable wafer bias power system 500 may include the first high voltage pulser 425 and the second high voltage pulser 430.

An interconnect board 505 may be electrically coupled with the first high voltage pulser 425 and the second high voltage pulser 430 or additional high voltage pulsers. In some embodiments, the interconnect board 505 may provide a high DC voltage to each of the first high voltage pulser 425 or the second high voltage pulser 430. In some embodiments, the interconnect board 505 may provide trigger signals to the first high voltage pulser 425 or the second high voltage pulser 430. In some embodiments, the interconnect board 505 may provide low voltage pulses to the first high voltage pulser 425 or the second high voltage pulser 430.

In some embodiments, the interconnect board 505 may include a controller or processor that includes one or more components of computational system 900. In some embodiments, one or more sensors may be included that measure a characteristic of the plasma chamber such as, for example, the electric field on the surface of a wafer, the uniformity of an electric field, the voltage on a first electrode 415, the voltage on a second electrode 420, the voltage across a resistor in one or more resistive output stages or one or more energy recovery circuits. Based on the measurement from the sensors, the voltage, pulse width, or pulse repetition frequency of the first high voltage pulser 425 and the second high voltage pulser 430 may be adjusted.

For example, if the voltage on the second electrode 420 is measured and determined to be lower than the voltage on the first electrode 415, which may cause an electric filed nonuniformity (e.g., differences less than about 5%, 10%, 15%, or 20%) on the surface of the wafer. The controller may adjust the pulse width of the control pulse being sent to the second high voltage pulser 430, which may increase the voltage produced by the second high voltage pulser 430 (e.g., by increasing the capacitive charging time) and, therefore, increasing the electric field on the second electrode. The process may repeat until the electric field across the surface of the wafer is uniform (e.g., within 10%, 15%, 20%, 25%, etc.).

As another example, the voltages across a first resistive output stage and a second resistive output stages may be measured. These voltages can correspond to the ion current flowing in the chamber. This current may be affected by the electrode voltage. If the ion current to the first electrode and the ion current to the second electrode are nonuniform or misaligned (e.g., a difference greater than 10%, 20% or 30%), then the controller may adjust the pulse width of the control pulse being sent to either the first high voltage pulser 425 or the second high voltage pulser 430, which may increase the voltage produced by the nanosecond pulser (e.g., by increasing the capacitive charging time) and, therefore, increasing the electric field on the corresponding electrode.

In some embodiments, pulses from the first high voltage pulser 425 and the second high voltage pulser 430 may pass to the energy recovery circuit 525 and to the plasma chamber 535 via a chamber interface board or the bias compensation circuit 510. The energy recovery circuit 525, for example, may include the resistive output stage 102 of nanosecond pulser system 100. As another example, the energy recovery circuit 525 may include the energy recovery circuit 305. As another example, the energy recovery circuit 525 may not be required. As another example, an energy recovery circuit 525 may be coupled with either or both the first high voltage pulser 425 or the second high voltage pulser 430. In some embodiments, the plasma chamber 535 may include a plasma chamber, an etch chamber, a deposition chamber, etc. In some embodiments, the effective circuit of the plasma chamber 535 may include load stage 106.

While two high voltage pulsers are shown, any number may be used. For example, multiple rings of electrodes may be coupled with multiple high voltage pulsers.

In some embodiments, the first high voltage pulser 425 may produce pulses that are different than pulses produced by the second high voltage pulser 430. For example, the first high voltage pulser 425 may provide pulses of at least 2 kV of pulsed output. In some embodiments, the second high voltage pulser 430 may provide pulses of at least 2 kV of pulsed output that are either the same or different than the pulses provided by the first high voltage pulser 425.

As another example, the first high voltage pulser 425 may produce pulses with a first pulse repetition frequency and the second high voltage pulser 430 may produce pulses with a second pulse repetition frequency. The first pulse repetition frequency and the second pulse repetition frequency may be the same or different. The first pulse repetition frequency and the second pulse repetition frequency may be in phase or out of phase with respect to each other.

As another example, the first high voltage pulser 425 may produce a first plurality of bursts with a first burst repetition frequency and the second high voltage pulser 430 may produce a second plurality of bursts with a second burst repetition frequency. Each burst may comprise a plurality of pulses. The first burst repetition frequency and the second burst repetition frequency may be the same or different. The first burst repetition frequency and the second burst repetition frequency may be in phase or out of phase with respect to each other.

In some embodiments, the first high voltage pulser 425 and the second high voltage pulser 430 may be water- or dielectric-cooled.

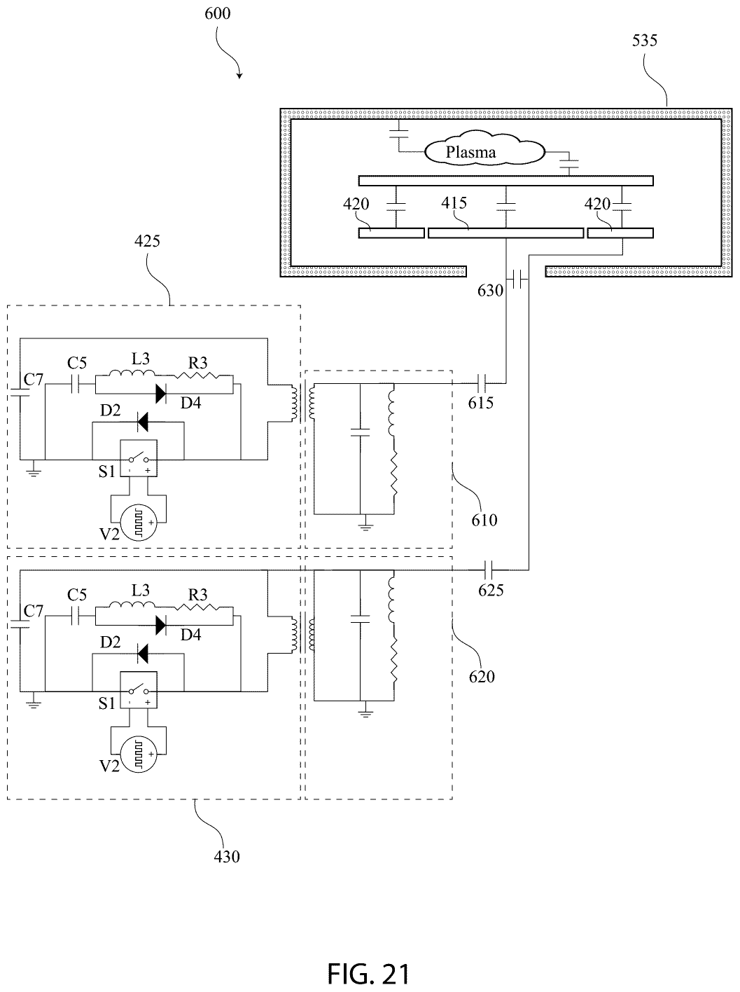

FIG. 21 is a schematic of a spatially variable wafer bias system 600 according to some embodiments. The spatially variable wafer bias system 600 may include a first high voltage pulser 425 and a second high voltage pulser 430 coupled with a plasma chamber 535.

In this example, the first high voltage pulser 425 includes a first resistive output stage 610 and a first bias capacitor 615. In some embodiments, the first resistive output stage 610 may not be used, and an energy recovery circuit may be used such as, for example, as shown in nanosecond pulser system 300.

In this example, the second high voltage pulser 430 includes a second resistive output stage 620 and a second bias capacitor 625. In some embodiments, the second resistive output stage 620 may not be used, and an energy recovery circuit may be used such as, for example, as shown in nanosecond pulser system 300.

A first electrode 415 and a second electrode 420 are disposed in the plasma chamber 535. In this example, the first electrode 415 is disc shaped and disposed within a central aperture of the second electrode 420. The first high voltage pulser 425 is electrically coupled with the first electrode 415 and the second high voltage pulser 430 is electrically coupled with the second electrode 420. In some embodiments, a stray coupling capacitance 630 can exist between the first high voltage pulser 425 and the second high voltage pulser 430. The stray coupling capacitance 630, for example, may be less than about 100 pF, about 1 nF, about 10 nF, etc.

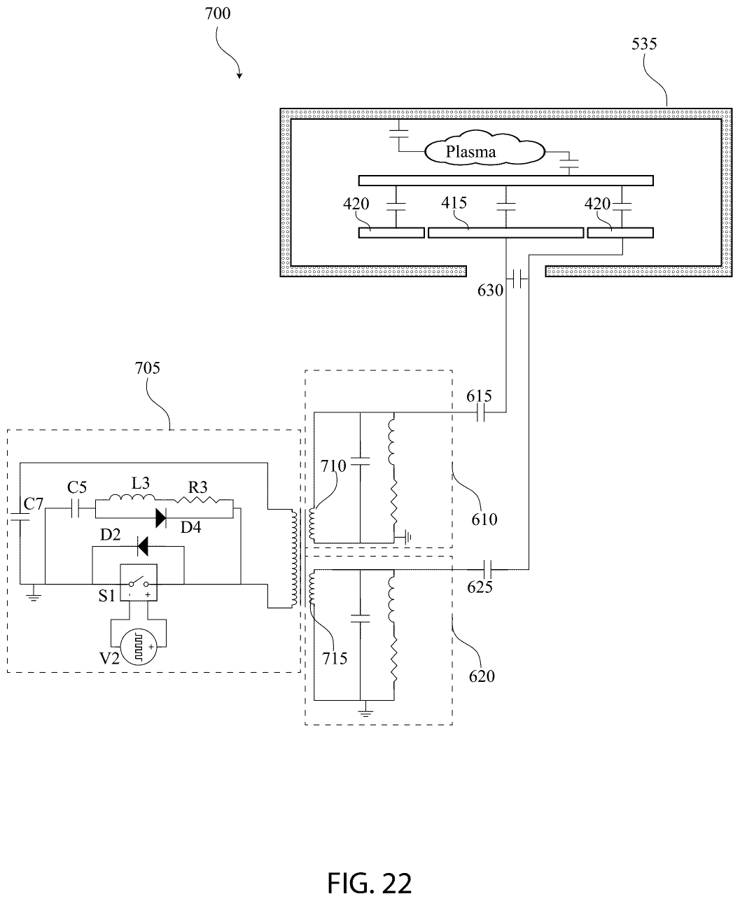

FIG. 22 is a schematic of a spatially variable wafer bias system 700 according to some embodiments. In this example, the spatially variable wafer bias system 700 utilizes multiple isolated secondary windings to provide different voltages on two different wafer spatial regions. The spatially variable wafer bias system 700 includes a single high voltage pulser 705. The single high voltage pulser 705 may include the pulser and transformer stage 101 shown in FIG. 16 or FIG. 18. In this example, two distinct sets of secondary windings can be wound around the transformer T1. A first secondary winding 710 may be electrically coupled with a first resistive output stage 610 and a first bias capacitor 615 forming a first electrode channel. A second secondary winding 715 may be electrically coupled with a second resistive output stage 620 and a second bias capacitor 625 forming a second electrode channel. In some embodiments, a stray coupling capacitance 630 can exist between the first electrode channel and the second electrode channel. The stray coupling capacitance 630, for example, may be less than about 100 pF, about 1 nF, about 10 nF, etc.

In some embodiments, a first energy recover circuit (e.g., energy recovery circuit 305) can be used instead of the first resistive output stage 610 and a second energy recover circuit (e.g., energy recovery circuit 305) can be used instead of the second resistive output stage 620. The first energy recovery circuit and the second energy recovery circuit may be arranged in parallel.

The voltage on the first electrode 415 and the second voltage on the second electrode 420 may depend on the number of windings of the first secondary windings and the second secondary windings.

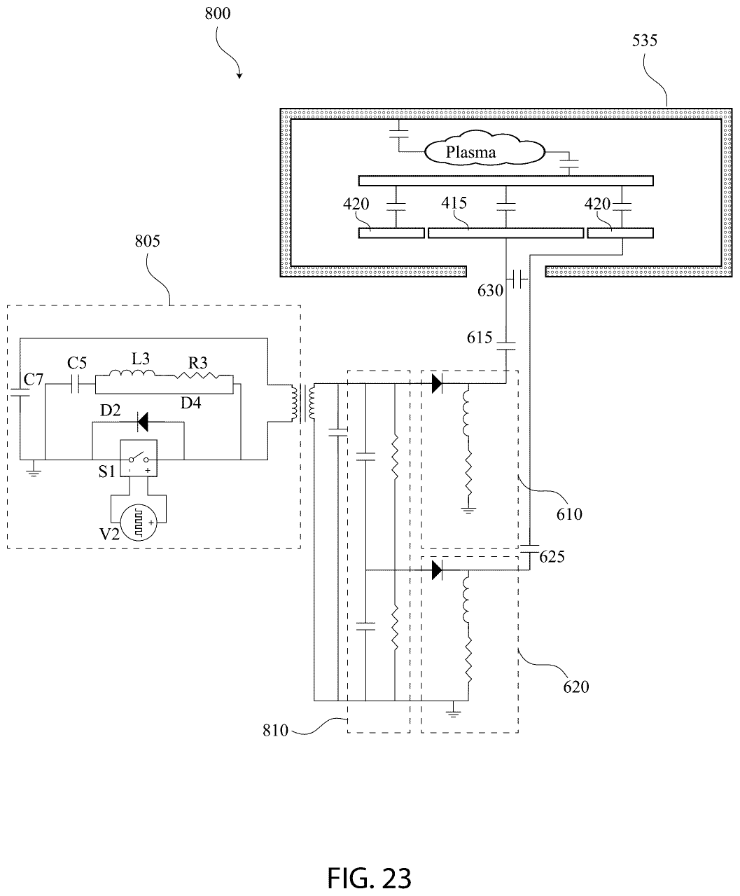

FIG. 23 is a schematic of a spatially variable wafer bias system 800 according to some embodiments. In this example, the spatially variable wafer bias system 800 utilizes a voltage divider to provide different voltages on two different wafer spatial regions. The spatially variable wafer bias system 800 includes a single high voltage pulser 805 and a voltage divider 810. The voltage divider 810 may include a plurality of resistors and capacitors. The value of the resistors and capacitors can be selected to provide the voltage ratio of the voltage of the pulses provided to the first electrode channel which provides pulses to the first electrode 415 and the voltage of the pulses provided to the second electrode channel which provides pulses to the second electrode 420.

The first electrode channel can include a first resistive output stage 610 and a first bias capacitor 615. The second electrode channel can include a second resistive output stage 620 and a second bias capacitor 625.

In some embodiments, a stray coupling capacitance 630 can exist between the first electrode channel and the second electrode channel. The stray coupling capacitance 630, for example, may be less than about 100 pF, about 1 nF, about 10 nF, etc.

In some embodiments, a first energy recover circuit (e.g., energy recovery circuit 305) can be used instead the first resistive output stage 610 and a second energy recover circuit (e.g., energy recovery circuit 305) can be used instead of the second resistive output stage 620. The first energy recovery circuit and the second energy recovery circuit may be arranged in parallel.

Unless otherwise specified, the term “substantially” means within 5% or 10% of the value referred to or within manufacturing tolerances. Unless otherwise specified, the term “about” means within 5% or 10% of the value referred to or within manufacturing tolerances.

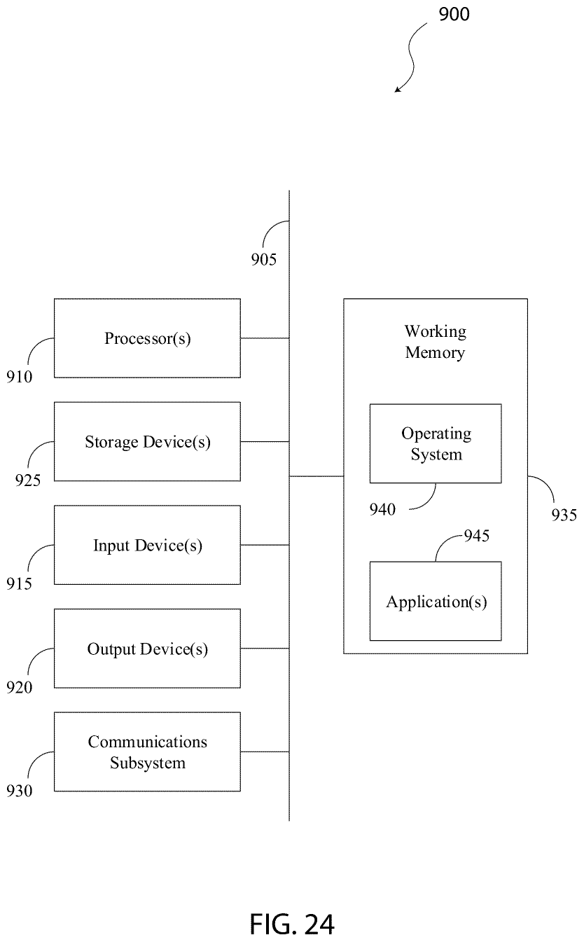

The computational system 900, shown in FIG. 24 can be used to perform any of the embodiments of the invention. As another example, computational system 900 can be used perform any calculation, identification and/or determination described here. The computational system 900 includes hardware elements that can be electrically coupled via a bus 905 (or may otherwise be in communication, as appropriate). The hardware elements can include one or more processors 910, including without limitation one or more general-purpose processors and/or one or more special-purpose processors (such as digital signal processing chips, graphics acceleration chips, and/or the like); one or more input devices 915, which can include without limitation a mouse, a keyboard and/or the like; and one or more output devices 920, which can include without limitation a display device, a printer and/or the like.

The computational system 900 may further include (and/or be in communication with) one or more storage devices 925, which can include, without limitation, local and/or network accessible storage and/or can include, without limitation, a disk drive, a drive array, an optical storage device, a solid-state storage device, such as a random access memory (“RAM”) and/or a read-only memory (“ROM”), which can be programmable, flash-updateable and/or the like. The computational system 900 might also include a communications subsystem 930, which can include without limitation a modem, a network card (wireless or wired), an infrared communication device, a wireless communication device and/or chipset (such as a Bluetooth device, an 802.6 device, a Wi-Fi device, a WiMax device, cellular communication facilities, etc.), and/or the like. The communications subsystem 930 may permit data to be exchanged with a network (such as the network described below, to name one example), and/or any other devices described herein. In many embodiments, the computational system 900 will further include a working memory 935, which can include a RAM or ROM device, as described above.

The computational system 900 also can include software elements, shown as being currently located within the working memory 935, including an operating system 940 and/or other code, such as one or more application programs 945, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 925 described above.

In some cases, the storage medium might be incorporated within the computational system 900 or in communication with the computational system 900. In other embodiments, the storage medium might be separate from a computational system 900 (e.g., a removable medium, such as a compact disc, etc.), and/or provided in an installation package, such that the storage medium can be used to program a general-purpose computer with the instructions/code stored thereon. These instructions might take the form of executable code, which is executable by the computational system 900 and/or might take the form of source and/or installable code, which, upon compilation and/or installation on the computational system 900 (e.g., using any of a variety of generally available compilers, installation programs, compression/decompression utilities, etc.) then takes the form of executable code.

Various embodiments are disclosed. The various embodiments may be partially or completely combined to produce other embodiments.

Numerous specific details are set forth herein to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A waveform generator, comprising:
a first voltage stage having:
a first voltage source;
a first switch, wherein a first terminal of the first voltage source is coupled to a first terminal of the first switch;
a first ground reference, wherein a second terminal of the first switch is coupled to the first ground reference;
a first transformer having a first transformer ratio, the first transformer comprising:
a primary winding coupled to a second terminal of the first voltage source and the first ground reference; and
a secondary winding including a first end and a second end,
wherein the first end is coupled to the first ground reference; and
a second voltage stage comprising:
a second voltage source;
a second switch, wherein a first terminal of the second voltage source is coupled to a first terminal of the second switch;
a second ground reference, wherein a second terminal of the second switch is coupled to the second ground reference;
a second transformer having a second transformer ratio, the second transformer comprising:
a primary winding coupled to a second terminal of the second voltage source and the second ground reference; and
a secondary winding including a first end and a second end, wherein the first end of the secondary winding of the second transformer is coupled to the second end of the secondary winding of the first transformer and the second end of the secondary winding of the second transformer is configured to be coupled to a load through a common node, wherein the secondary winding of the first transformer is coupled in series with the secondary winding of the second transformer, and wherein the primary winding of the first transformer is not coupled to the primary winding of the second transformer.

2. The waveform generator of claim 1, wherein the first voltage source comprises a capacitive element.

3. The waveform generator of claim 1, wherein the common node is configured to be capacitively coupled to a plasma formed in a processing region of a plasma processing system.

4. The waveform generator of claim 3, wherein the common node is coupled to a biasing electrode disposed within a substrate support disposed within the plasma processing system.

5. The waveform generator of claim 1, further comprising a third voltage stage comprising:
a third voltage source;
a third switch, wherein a first terminal of the third voltage source is coupled to a first terminal of the third switch;
a third ground reference, wherein a second terminal of the third switch is coupled to the third ground reference;
a third transformer having a third transformer ratio, the third transformer comprising:
a primary winding coupled to a second terminal of the third voltage source and the third ground reference; and
a secondary winding including a first end and second end, the first end coupled to the second end of the secondary winding of the second transformer and the second end of the third transformer is configured to be coupled to the load through the common node.

6. The waveform generator of claim 1, wherein the first switch is coupled between a first end of the primary winding of the first transformer and a second end of the primary winding of the first transformer.

7. The waveform generator of claim 1, wherein the first voltage source and the second voltage source are each configured to provide different voltages.

8. The waveform generator of claim 1, wherein a voltage at the first voltage source and a voltage at the second voltage source are individually adjustable.

9. A waveform generator, comprising:
a first voltage stage comprising:
a first voltage source;
a first switch, wherein a first terminal of the first voltage source is coupled to a first terminal of the first switch;
a first ground reference, wherein a second terminal of the first switch is coupled to the first ground reference;
a first transformer having a first transformer ratio, the first transformer comprising:
a primary winding coupled to a second terminal of the first voltage source and the first ground reference; and
a secondary winding including a first end and a second end,
wherein the first end is coupled to the first ground reference; and
a second voltage stage comprising:
a second voltage source;
a second switch, wherein a first terminal of the second voltage source is coupled to a first terminal of the second switch;
a second ground reference, wherein a second terminal of the second switch is coupled to the second ground reference;
a second transformer having a second transformer ratio, the second transformer comprising:
a primary winding coupled to a second terminal of the second voltage source and the second ground reference; and
a secondary winding including a first end and a second end, wherein the first end of the secondary winding of the second transformer is coupled to the second end of the secondary winding of the first transformer and the second end of the secondary winding of the second transformer is configured to be coupled to a load through a common node, wherein the secondary winding of the first transformer is coupled in series with the secondary winding of the second transformer, wherein the first switch comprises a transistor that is a metal-oxide-semiconductor field-effect transistor (MOSFET), and a gate drive circuit, and wherein the first switch is coupled between a first end of the primary winding of the first transformer and a second end of the primary winding of the first transformer.

10. The waveform generator of claim 9, wherein the primary winding of the first transformer is not coupled in parallel with the primary winding of the second transformer.

11. A method of generating a voltage waveform, comprising:
generating a first voltage pulse at a common node at a first time by closing a first switch that has a first terminal and a second terminal, wherein:
the first terminal of the first switch is coupled to a first terminal of a first voltage source;
a second terminal of the first voltage source is coupled to a first terminal of a primary winding of a first transformer, the first transformer having a first transformer ratio;
the second terminal of the first switch is coupled to a second terminal of the primary winding of the first transformer and to ground; and
the common node is coupled to a first terminal of a secondary winding of the first transformer; and
generating a second voltage pulse at the common node at a second time by closing a second switch that has a first terminal and a second terminal, wherein:
the first terminal of the second switch is coupled to a first terminal of a second voltage source;
a second terminal of the second voltage source is coupled to a first terminal of a primary winding of a second transformer, the second transformer having a second transformer ratio;
the second terminal of the first switch is coupled to a second terminal of the primary winding of the second transformer and to ground;
a first bias voltage is generated by the second voltage source between the first terminal and the second terminal of the second voltage source; and
a first terminal of a secondary winding of the second transformer is coupled to a second terminal of the secondary winding of the first transformer,
wherein the common node is disposed between the first terminal of the secondary winding of the first transformer and a load, wherein the secondary winding of the first transformer is coupled in series with the secondary winding of the second transformer, and wherein the primary winding of the first transformer is not coupled to the primary winding of the second transformer.

12. The method of claim 11, wherein the first voltage pulse and the second voltage pulse overlap in time.

13. The method of claim 11, wherein the common node is coupled to a biasing electrode disposed within a substrate support disposed within a plasma processing system.

14. The method of claim 11, wherein the first transformer ratio is different than the second transformer ratio.

15. The method of claim 11, wherein the first time overlaps with the second time.

16. The method of claim 11, further comprising:
generating a third voltage pulse at the common node at a third time by closing a third switch that has a first terminal and a second terminal, wherein:
the first terminal of the third switch is coupled to a first terminal of a third voltage source;
a second terminal of the third voltage source is coupled to a first terminal of a primary winding of a third transformer, the third transformer having a third transformer ratio;
the second terminal of the third switch is coupled to a second terminal of the primary winding of the third transformer and to ground;
a second bias voltage is generated by the third voltage source between the first terminal and the second terminal of the third voltage source; and
a first terminal of a secondary winding of the second transformer is coupled to a second terminal of the secondary winding of the first transformer.

17. A non-transitory computer-readable medium for generating a waveform, comprising instructions executable by one or more processors to
generate a first voltage pulse at a common node at a first time by closing a first switch that has a first terminal and a second terminal, wherein:
the first terminal of the first switch is coupled to a first terminal of a first voltage source;
a second terminal of the first voltage source is coupled to a first terminal of a primary winding of a first transformer, the first transformer having a first transformer ratio;
the second terminal of the first switch is coupled to a second terminal of the primary winding of the first transformer and to ground; and
the common node is coupled to a first terminal of a secondary winding of the first transformer; and
generate a second voltage pulse at the common node at a second time by closing a second switch that has a first terminal and a second terminal, wherein:
the first terminal of the second switch is coupled to a first terminal of a second voltage source;
a second terminal of the second voltage source is coupled to a first terminal of a primary winding of a second transformer, the second transformer having a second transformer ratio;
the second terminal of the first switch is coupled to a second terminal of the primary winding of the second transformer and to ground;
a first bias voltage is generated by the second voltage source between the first terminal and the second terminal of the second voltage source; and
a first terminal of a secondary winding of the second transformer is coupled to a second terminal of the secondary winding of the first transformer,
wherein the common node is disposed between the first terminal of the secondary winding of the first transformer and a load, and wherein the secondary winding of the first transformer is coupled in series with the secondary winding of the second transformer.
